(19) United States
(12) Patent Application Publication
(10) Pub. No.: US 2026/0142658 A1
(43) Pub. Date: May 21, 2026

(54) SWITCHING CIRCUITRY, RELATED INTEGRATED CIRCUIT, ULTRASONIC PROBE, ULTRASONIC SYSTEM AND METHOD

(71) Applicant: STMicroelectronics International N.V., Geneva (CH)

(72) Inventors: Marco TERENZI, Pavia (IT); Alessandro Salvatore BUCCATO, Mercogliano (IT); Davide Ugo GHISU, Milano (IT); Federico GUANZIROLI, Lentate Sul Seveso (IT); Gabriele LINGUA, Pont Saint Martin (IT); Stefano OTTAVIANI, Magenta (IT)

(73) Assignee: STMicroelectronics International N.V., Geneva (CH)

(21) Appl. No.: 19/380,798

(22) Filed: Nov. 5, 2025

(30) Foreign Application Priority Data
Nov. 15, 2024 (IT) 102024000025827

(51) Int. Cl. H03K 17/693; G01N 29/34; H03K 17/687; H03K 19/20

(52) U.S. Cl. CPC H03K 17/693; G01N 29/343; H03K 17/6871; H03K 19/20

(57) ABSTRACT

A switching circuit includes a first terminal that receives a signal, and a second terminal connected to a load. First and second transistors are connected in series between the first and second terminals, each of the first and the second transistors including a control terminal connected to a common control node, a capacitance being connected between the common control node and an intermediate point between the first and second transistors. A control circuit charges the capacitance as a function of a set signal, and discharge the capacitance as a function of a reset signal. A first diode is connected to the first terminal and a first capacitance. A second diode is connected to the first terminal and a second capacitance. An electronic converter circuit is configured to charge the first capacitance to a first voltage and the second capacitance to a second voltage.

### BACKGROUND

### Technical Field

Embodiments of the present disclosure relate to a (e.g., high-voltage) switching circuitry, such as an integrated (e.g., high-voltage) switching circuitry.

### Description of the Related Art

Conventional echography systems comprise one or more ultrasonic transducers, usually an array of ultrasonic transducers, that are used to transmit an ultrasound beam and then receive the reflected beam from a target object.

For example, FIG. 1 shows a simplified block diagram of an ultrasonic system, such as an echography system.

In the example considered, the system comprises a transducer 200. Generally, the transducer 200 may be any type of ultrasonic transducer such as capacitive micromachined ultrasonic transducer (cMUTS) or piezoelectric transducer.

The transducer 200 is connected to a signal generation circuitry 100 and an analysis circuitry 110. For example, the signal generation circuitry 100 may include a control circuit 102 and a driver circuit 104 configured to generate a drive or transmission signal TX to be applied to the transducer 200. For example, the control circuit 102 may provide a control signal, which activates or deactivates the driver circuit 104. The driver circuit 104, when activated, may then apply to the transducer 200 via the transmission signal TX a voltage with a square or sinusoidal waveform.

Accordingly, when the driver circuit 104 is activated, the transmission signal TX will be a periodic voltage signal with a given frequency and amplitude oscillating between a minimum voltage and a maximum voltage. For example, in case of echography systems, the frequency of the transmission signal TX is often between 1 and 20 MHz (Megahertz). Moreover, the transmission signal TX is often a high voltage drive signal, i.e., a signal wherein the maximum voltage is greater than 10 V, typically between 20 V and 200 V, and/or the minimum voltage is smaller than −10 V, typically between −20 V and −200 V. For example, the transmission signal TX often oscillates between 0 and +200 V, −200 V and 0 V, or −100 V and +100V.

Accordingly, when the driver circuit 104 is activated, the transducer 200 will be stimulated and generate an ultrasound signal to be transmitted to a target object. Conversely, when the driver circuit 104 is deactivated, the transducer 200 may be used to receive an ultrasound signal, i.e., an echo, reflected from the target object. For this reason, the transducer 200 should be placed in a high impedance state when the driver circuit 104 is deactivated. This may be obtained by an appropriate configuration of the driver circuit 104 or as shown in FIG. 1 by an optional transmit-and-receive (T/R) switch 120, which selects whether the transducer 200 is connected to the driver circuitry 100 or the analysis circuitry 110. For example, as shown in FIG. 1, the control circuit 102 may control for this purpose also the T/R switch 120.

Conversely, the analysis circuitry 110 is configured to analyze the received signal RX, i.e., the voltage at the transducer 200 when the driver circuit 104 is deactivated. For example, the analysis circuitry 110 may comprise an amplifier circuit 112, such as a low noise amplifier (LNA), and a processing circuit 116 configured to analyze the amplified voltage at the transducer 200. Generally, the analysis circuitry 110 may comprise also other components, such as a filter and/or an analog-to-digital (A/D) converter 114 interposed between the amplifier circuit 112 and the processing circuit 116.

Generally, the signal generation circuitry 100 and the analysis circuitry 110 may be connected also to a user interface 130 comprising, e.g., display means and user input means.

FIG. 2 shows an example, in which a plurality of transducers 200 is used. For example, three transducers 200a, 200b and 200c are shown in FIG. 2. For example, the transducers 200 may be arranged in an array or matrix 20 comprising at least one row and a plurality of columns.

Generally, a respective driver circuit 104 could be provided for each transducer 200a-200c. Conversely, in FIG. 2 is shown the case, wherein at least a subset of the transducers 200a-200c is driven by the same driver circuit 104. In this case, the system comprises usually a switching circuitry 30, such as a multiplexer, configured to connect, at a given time instant, the driver circuit 104 to at least one (or possibly none) of the transducers 200a-200c. For example, the switching of the switching circuitry 30 may again be controlled by the signal generation circuitry 100, e.g., the control circuit 102.

For example, in case a single driver circuit 104 is used for the complete array 20, the switching circuitry 30 may be a so-called matrix switch, which permits a selection of the row and column of the array. Reference can be made for this purpose, e.g., to United States Patent Application no. US 2010/0152587 A1, which discloses various solutions for driving a plurality of transducers with one or more driver circuits and which is incorporated herein by reference.

As shown in FIG. 3, the switching circuitry 30 may comprise, for example, one or more switches 300 configured to connect one or more transducers 200a-200c to a given signal generation circuitry 100, in particular a given driver circuit 104. For example, in FIG. 3 are shown three switches 300a, 300b and 300c, wherein each of the switches 300a-300c is interposed between the driver circuit 104 and a respective transducer 200a-200c.

The same applies also to the analysis circuitry 110, i.e., a switching circuitry could be provided to connected one or more amplifiers 112 to respective subsets of transducers 200.

In this case, the target may be “scanned” by performing a series of measurements in which a focused ultrasonic wave is generated by a first group of transducers 200 and the reflected ultrasonic wave is received by a second group of transducers 200. For example, in case of an ultrasonic system, one or more switching circuits 30 and one or more arrays 20 of transducers 200 are mounted within an ultrasonic probe, wherein the probe is connected via a cable to a measurement device comprising the circuits 100, 110, 120 and 130.

Accordingly, the switches 300a-300c of these switching circuitries 30 should support high voltages and currents, and high frequencies and slew-rates.

FIG. 4 shows in this respect a possible implementation of such a switch 300.

Specifically, in the example considered, the switch 300 comprises two terminals T1 and T2 being either connected together (closed) or disconnected (opened), and two control terminals SET and RESET for receiving control signals indicating whether the two terminals T1 and T2 should be electrically connected (conductive) or disconnected (non-conductive), respectively.

Specifically, in the example considered, the switch 300 is implemented with two Field Effect Transistors (FET) SW₁ and SW₂ connected back-to-back (source nodes connected/shorted together) to allow for bidirectional operation. For example, these transistors may be implemented as Double-Diffused MOS (Metal-Oxide-Semiconductor). Basically, this connection is preferable due to the parasitic body diodes (as shown in FIG. 4) which would provide a conduction path from source to drain during the positive or negative phase of the drive signal TX. Accordingly, in the example considered, the drain of the switch SW₁ is connected to the terminal T1, the drain of the switch SW₂ is connected to the terminal T2 and the sources of the switches SW₁ and SW₂ are connected (e.g., directly) to a common node S.

Also, the gate nodes of the transistors SW₁ and SW₂ are connected (e.g., directly) together at a common node G and controlled by a control circuit 310 as a function of the control signals provided at the terminals SET and RESET Specifically, the control circuit 310 should ensure that:
the gate-source voltage V_{GS} of the transistors (i.e., the voltage between the nodes G and S) is greater than the threshold voltage of the transistors SW₁ and SW₂ when the control signal SET indicates that the switch 300 should be closed, and
the gate-source voltage V_{GS} of the transistors is smaller than the threshold voltage of the transistors SW₁ and SW₂ when the control signal RESET indicates that the switch 300 should be opened.

However, when the switch 300 is closed, the source voltage at the node S will be close to the drain voltage of the transistor SW₁, and the source voltage will thus follow the drive signal TX. Thus, in order to switch the switch 300 on, the node G should be connected to a high voltage, e.g., the maximum voltage of the drive signal TX. However, this implies that a high-voltage (HV) supply has to be provided to the control circuit 310, i.e., the cable connecting an ultrasonic probe to the measurement device needs to provide a high-voltage supply.

Conversely, United States Patent Application no. US 2005/0146371 A1 discloses possible implementations of the control circuit 310 permitting that the control circuit 310 operates with low voltage signals, e.g., in the range between 0 V and 5 V.

Basically, this document proposes to change the state (on or off) of the switch 300 only when the terminal T1 is connected to ground GND.

Basically, as shown in FIG. 5, the circuit of document US 2005/0146371 A1 comprises a first circuit 312 configured to charge the node G when the switch 300 should be closed (e.g., when the signal SET is high). Specifically, in document US 2005/0146371 A1 the circuit 312 comprises a switch (M4 in the cited document) configured to connect the node G to a low voltage source V_{g0} (e.g., 5 V), thereby charging the node G to approximately V_{g0}, because the node S is connected to ground via the diode of the transistor SW₁.

The circuit comprises moreover a second circuit 314 configured to discharge the node G when the switch 300 has to be opened (e.g., when the signal RESET is high). Specifically, in document US 2005/0146371 A1 the circuit 314 comprises a gate clamp (MI in the cited document) configured to short circuit the node G to the node S, thereby discharging the node G to approximately 0 V, because again the node S is connected to ground via the diode of the transistor SW₁.

Accordingly, in document US 2005/0146371 A1, the node G is charged to a low voltage compared to the maximum voltage of the drive signal TX. However, the parasitic gate-source capacitance C_{GS} of the transistors SW₁ and SW₂ will retain this voltage. For this reason, once the gate-source voltage has stabilized (either 5 V or 0 V) the node G may be disconnected and the gate-source voltage V_{GS} remains substantially constant, thereby maintaining the switch 300 closed/opened when the signal generation circuitry 100 drives the switch 300 and/or the voltage at the transducer 200 has to be provided to the analysis circuitry 110.

Those of skill in the art will appreciate that such bidirectional high-voltage switches 300 may also be used in other applications, such as for example liquid crystal displays (LCD) requiring high voltages (e.g., about 100 V), or automotive applications.

Unfortunately, such switches 300, which do not use a high-voltage for driving the node G, often also identified as HV-less high-voltage switches 300, also have disadvantages.

On the one hand, leakage current may still discharge the node G. In this regards, document US 2005/0146371 A1 proposes to periodically reprogram the gate-source voltage V_{GS}. Conversely, U.S. Pat. No. 10,177,759 B1 disclose that the switching activity at the node T1 may be used to maintain the switching state of the electronic switch.

However, such solutions often imply a possible memory effect, wherein the rise and/or fall times at the node T1 may not be constant. For example, when a first high-voltage pulse is applied to the input T1 of the switch 300, some internal HV nodes must usually follow the HV signal to maintain the correct polarization of all internal blocks. In these topologies, the only signal that can charge these nodes to the HV value is the input signal itself. However, this implies that during the first pulses, some of the current from the input T1 is used to pre-charge the floating nodes. Once the floating nodes reach the final HV value, they no longer need to be charged and all the current from the input T1 can be used to drive the load, e.g., the ultrasonic transducer 200. The waveform produced at the output T2 of the switch 300 is thus affected by the amount of charge subtracted from the input T1 during the first pulses, and can cause an observable difference in the rise/fall time of the first pulses compared to the subsequent pulses. This problem is called the “memory effect” and is one of the main disadvantages of HV-less high voltage switches.

### BRIEF SUMMARY

Accordingly, various embodiments of the present disclosure provide improved solutions for high-voltages switching circuits.

According to one or more embodiments, one or more of the above objectives is achieved by means of a switching circuitry having the features specifically set forth in the claims that follow. Embodiments moreover concern a related integrated circuit, ultrasonic probe, ultrasonic system and method.

Example embodiments of the present disclosure are defined by the appended independent claims. The claims are an integral part of the technical teaching of the disclosure provided herein.

As mentioned before, various embodiments of the present disclosure relate to a switching circuit, e.g., implemented in an integrated circuit. The switching circuit comprises a first terminal configured to receive a signal oscillating between a maximum value and a minimum value, and a second terminal configured to be connected to a load, such as an ultrasound transducer. A first transistor and a second transistor are connected in series between the first terminal and the second terminal, wherein each of the first transistor and the second transistor includes a control terminal connected to a common control node, wherein a capacitance is connected between the common control node and an intermediate point between the first transistor and the second transistor, wherein the first and the second transistor are rendered conductive or non-conductive as a function of the voltage at the capacitance. In various embodiments, the switching circuit comprises also a positive power supply terminal and a negative power supply terminal for receiving a supply voltage, wherein a value of the supply voltage is smaller than an amplitude of the signal. Moreover, in various embodiments, the switching circuit comprises a control circuit supplied by the supply voltage. Specifically, the control circuit comprises a set circuit configured to charge the capacitance as a function of a set signal, and a reset circuit configured to discharge the capacitance as a function of a reset signal.

According to a first aspect of the present disclosure, the switching circuit comprises also a first diode, a second diode and an electronic converter circuit. Specifically, an anode of the first diode is connected to the first terminal and a cathode of the first diode is connected to a first node, wherein the first node is connected to a first capacitance. A cathode of the second diode is connected to the first terminal and an anode of the second diode is connected to a second node, wherein the second node is connected to a second capacitance. The electronic converter circuit is supplied by the supply voltage and is configured to charge the first capacitance to a first voltage and the second capacitance to a second voltage, whereby the first node and the second node may be pre-charged to respective voltages.

For example, in various embodiments, the first voltage is in a range between 70% and 130%, preferably between 85% and 115%, of the maximum value of the signal received at the first terminal, and/or the second voltage is in a range between 70% and 130%, preferably between 85% and 115%, of the minimum value of the signal received at the first terminal. For example, in the context of ultrasonic systems the maximum value may be at least 100 V and the supply voltage may be smaller than 12 V. In various embodiments, the minimum value is negative.

For example, in various embodiments, the electronic converter circuit comprises a boost converter configured to generate the first voltage at the first node. Additionally or alternatively, the electronic converter circuit may comprise an inverting buck-boost converter configured to generate the second voltage at the second node.

For example, in various embodiments, the electronic converter circuit comprises a third terminal and a fourth terminal configured to be connected to an inductance. In various embodiments, a first electronic switch is connected between the third terminal and the positive power supply terminal, a second electronic switch is connected between the fourth terminal and the negative power supply terminal, a third electronic switch or a third diode is connected between the third terminal and the second node, and a fourth electronic switch or a fourth diode connected between the fourth terminal and the first node. In various embodiments, a first feedback circuit is configured to provide a first feedback signal indicative of the voltage at the first node, and a second feedback circuit configured to provide a second feedback signal indicative of the voltage at the second node. In this case, the electronic converter circuit may comprise a converter control circuit configured to drive the first electronic switch and the second electronic switch, and optionally the third electronic switch and the fourth electronic switch, in order to regulate the first feedback signal to a first reference voltage and the second feedback signal to a second reference voltage. For example, in various embodiments, the converter control converter operates periodically for a first time-period in a boost mode and for a second time-period in an inverting buck-boost mode.

According to a second aspect of the present disclosure, the control circuit comprises a fifth diode having an anode connected to the intermediate point between the first transistor and the second transistor and a cathode connected to a first supply node, and a sixth diode having a cathode connected to the intermediate point between the first transistor and the second transistor and an anode connected to a second supply node. Moreover, one or more diodes are connected in series between the first supply node and the second supply node. Specifically, a logic inverter is supplied by the voltage between the first supply node and the second supply node, wherein an input of the logic inverter is connected to the intermediate point and an output of the logic inverter is connected to the common control node. In this case, the set circuit may be configured to connected the first supply node to the positive power supply terminal as a function of the set signal and the reset circuit may be configured to connected the second supply node to the negative power supply terminal as a function of the reset signal. In various embodiments, the switching circuits comprises also a clamp circuit configured to connect the intermediate point to ground as a function of the set signal and the reset signal.

### BRIEF DESCRIPTION OF THE SEVERAL VIEWS OF THE DRAWINGS

Embodiments of the present disclosure will now be described with reference to the annexed drawings, which are provided purely by way of non-limiting example and in which:

FIGS. 1, 2 and 3 shows examples of ultrasonic systems;

FIGS. 4 and 5 show examples of high voltage switching circuits adapted to be used in the systems of FIGS. 1 to 3;

FIGS. 6 and 7 show embodiments of a first control circuit for a high voltage switching circuit in accordance with the present disclosure;

FIG. 8 shows a first embodiment of a set circuit of the control circuit of FIGS. 6 and 7;

FIG. 9 shows a first embodiment of a reset circuit of the control circuit of FIGS. 6 and 7;

FIG. 10 shows a second embodiment of a reset circuit of the control circuit of FIGS. 6 and 7;

FIG. 11 shows a third embodiment of a reset circuit of the control circuit of FIGS. 6 and 7;

FIG. 12 shows a second embodiment of a set circuit of the control circuit of FIGS. 6 and 7;

FIG. 13 shows a first embodiment of a maintenance circuit of the control circuit of FIGS. 6 and 7;

FIGS. 14A, 14B, 15A and 15B show embodiments of the operation of the maintenance circuit of FIG. 13;

FIG. 16 shows a second embodiment of a control circuit of FIGS. 6 and 7;

FIG. 17 shows an embodiment of an inverter of the control circuit of FIG. 16;

FIG. 18A shows an embodiment of a set operation of the control circuit of FIG. 16;

FIG. 18B shows an embodiment of a reset operation of the control circuit of FIG. 16;

FIGS. 19A, 19B, 20A and 20B show embodiments of a maintenance operation of the control circuit of FIG. 16;

FIG. 21 shows a further embodiment of a high voltage switching circuit;

FIG. 22 shows an embodiment of an electronic converter adapted to be used in the high voltage switching circuit of FIG. 21;

FIGS. 23A and 23B show embodiments of the operation of the electronic converter of FIG. 22; and

FIG. 24 shows an embodiment of an ultrasonic systems according to the present disclosure.

### DETAILED DESCRIPTION

In the following description, numerous specific details are given to provide a thorough understanding of embodiments. The embodiments can be practiced without one or several specific details, or with other methods, components, materials, etc. In other instances, well-known structures, materials, or operations are not shown or described in detail to avoid obscuring aspects of the embodiments.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The references provided herein are for convenience only and do not interpret the scope or meaning of the embodiments.

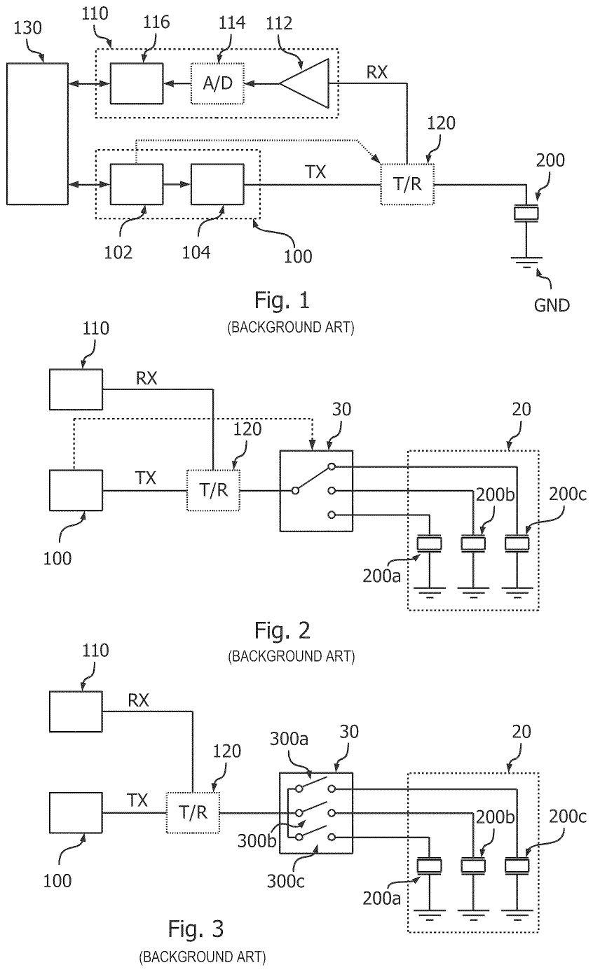

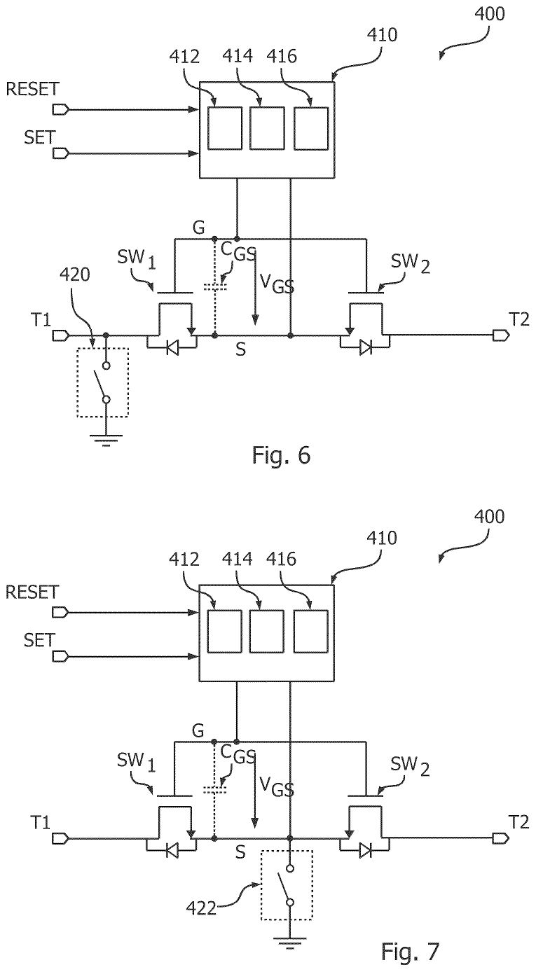

In the following FIGS. 6 to 24 parts, elements or components which have already been described with reference to FIGS. 1 to 5 are denoted by the same references previously used in such Figures; the description of such previously described elements will not be repeated in the following in order not to overburden the present detailed description.

As mentioned in the foregoing, the present disclosure relates to a high voltage switching circuitry 400. For example, such switching circuitry 400 may be used in place of the switches 300 disclosed in the foregoing. Accordingly, the respective description will not be repeated again.

FIG. 6 shows a first embodiment of the switching circuitry 400 in line with the disclosure of document U.S. Pat. No. 10,177,759 B1. Generally, also the switching circuitry 400 of the present disclosure comprises two terminals T1 and T2 being either connected together (closed/conductive condition) or disconnected (opened/non-conductive condition), and two control terminals SET and RESET for receiving control signals indicating whether the two terminals T1 and T2 should be connected together or disconnected, respectively.

Specifically, in the embodiment considered, the switch 400 is implemented with two n-channel FET (Field Effect Transistors) SW₁ and SW₂ connected back-to-back (source nodes shorted together) to allow for bipolar and bidirectional operation. For example, these transistors may be implemented as Double-Diffused MOS (DMOS). As mentioned in the foregoing, this connection is preferable due to the parasitic body diodes of the transistors SW₁ and SW₂.

Accordingly, in the embodiment considered, the drain of the switch SW₁ is connected (e.g., directly) to the terminal T1, the drain of the switch SW₂ is connected (e.g., directly) to the terminal T2 and the sources of the switches SW₁ and SW₂ are connected (e.g., directly) to a common node S. Also the gates of the transistors SW₁ and SW₂ are connected (e.g., directly) together at a common node G and controlled by a control circuit 410 as a function of the control signals provided at the terminal SET and RESET. Specifically, the control circuit 410 is configured to ensure that:
the gate-source voltage V_{GS} of the transistors SW₁ and SW₂ (i.e., the voltage between the node G and the node S) is greater than the threshold voltage of the transistors SW₁ and SW₂ when the control signal SET is asserted and indicates that the switch 400 should be closed (e.g., when the signal SET is high), and
the gate-source voltage V_{GS} of the transistors SW₁ and SW₂ is smaller than the threshold voltage of the transistors SW₁ and SW₂ when the control signal RESET is asserted and indicates that the switch 400 should be opened (e.g., when the signal RESET is high).

Similar to document US 2005/0146371 A1, also the control circuit 410 of the present disclosure may operate with low voltage signals, e.g., in the range between 0 V and 5 V, preferably between 0 V and 3.3 V. For this purpose, the state of the switch 400 should be changed only when the node S is connected (substantially) to ground GND and the drive signal TX is deactivated.

As mentioned in the foregoing, the node S may be connected to ground GND via the diode of the switch SW₁ when the node T1 is connected to ground GND. For example, as described in the foregoing, the terminal T1 may be connected to ground GND via the driver circuit 104.

However, generally, when the drive signal TX is deactivated, the terminal T1 may also be in a high impedance state, i.e., floating. For example, the terminal T1 may be floating, e.g., by disconnecting the terminal T1 or connecting the terminal T1 to the analysis circuitry 110 via the T/R switch 120. In this case, the switching circuitry 400 may comprise a clamp circuit 420 configured to connect the terminal T1 to ground GND when the state of the switch 400 has to be changed, e.g., when the signal SET is asserted (e.g., is set to high) or the signal RESET is asserted (e.g., is set to high). For example, such a clamp circuit 420 may comprise an electronic switch, such as an n-channel FET, connected between the terminal T1 and ground GND.

Conversely, FIG. 7 shows an embodiment in which a similar clamp circuit 422 is used to directly connect the node S to ground GND. For example, such a clamp circuit 422 may comprise an electronic switch, such as an n-channel FET, connected between the node S and ground GND. This embodiment may thus ensure that the node S is connected to ground GND, independently from fact whether the node T1 is connected to ground or floating.

In the embodiment considered, the control circuit 410 comprises three sub-circuits. The first (set) circuit 412 is configured to charge the gate-source capacitance C_{GS} between the node G and the node S when the signal SET is asserted and indicates that the switch 400 has to be closed (e.g., when the signal SET is high), i.e., the transistors SW₁ and SW₂ have to be closed. The second (reset) circuit 414 is configured to discharge the gate-source capacitance C_{GS} between the node G and the node S when the signal RESET is asserted and indicates that the switch 400 has to be opened (e.g., the signal RESET is high), i.e., the transistors SW₁ and SW₂ have to be opened. The third circuit 416 is configured to maintain the state of the switch 400 when the signals SET and RESET are de-asserted and indicate that the state of the switch 400 should be maintained (e.g., when the signals SET and RESET are low) and the drive signal TX is activated.

In various embodiments, the maintenance circuit 416 is omitted. In fact, as disclosed in document US 2005/0146371 A1, the set circuit 412 and the reset circuit 414 may reprogram periodically the state of the switch 400.

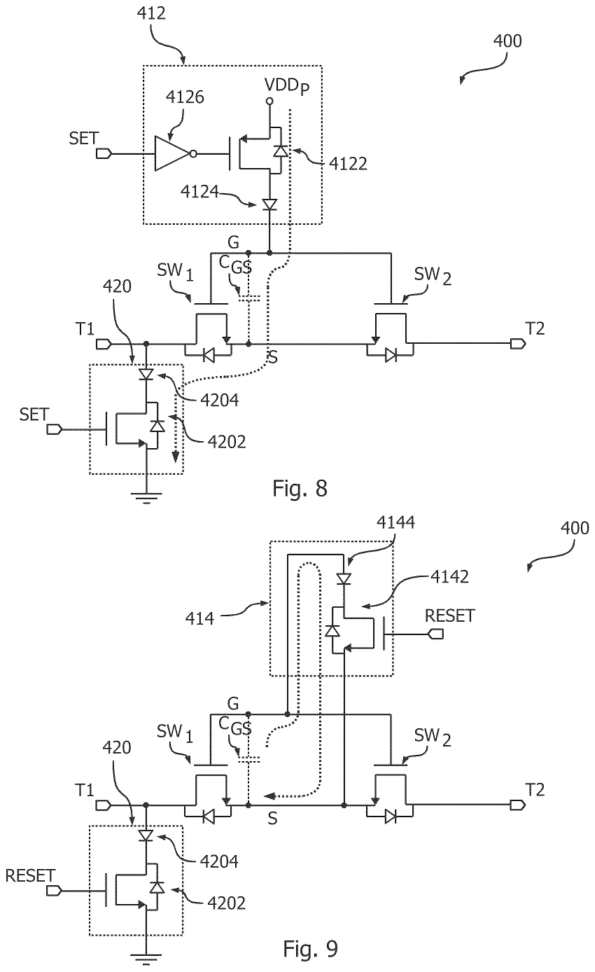

FIG. 8 shows a possible embodiment of the set circuit 412. As mentioned in the foregoing, the circuit 412 should charge the gate-source capacitance C_{GS} when the signal SET is asserted and indicates that the switch 400 has to be closed (e.g., when the signal SET is high). Moreover, as mentioned in the foregoing, the external control circuit generating the signals SET and RESET (e.g., the control circuit 102) ensures that the signal SET tries to close the switch 400 when the drive signal TX applied to the terminal T1 is deactivated.

In the embodiment considered, in order to switch on the switch 400, at least one of the nodes T1, T2 and S should be connected to ground GND. As mentioned in the foregoing, this may be ensured directly by the signal generation circuitry 100 (e.g., the driver circuit 104) and/or by a clamp circuit 420/422 in the switch 400 and/or a similar clamp circuit connected to the node T2.

For example, in the embodiment considered, a clamp circuit 420 is used. For example, in the embodiment considered, the clamp circuit 420 comprises an electronic switch 4202, such as a n-channel FET, and a diode 4204 connected in series between the terminal T1 and ground GND. Specifically, in the embodiment considered, the source of the transistor 4202 is connected (e.g., directly) to ground GND, the drain of the transistor 4202 is connected (e.g., directly) to the cathode of the diode 4204, and the anode of the diode 4204 is connected (e.g., directly) to the terminal T1, i.e., the drain of the transistor SW₁. Accordingly, when a positive voltage is applied to the gate of the transistor 4202, the transistor 4202 will be closed, i.e., be conductive, and the terminal T1 will be short-circuited to ground GND. Conversely, the diode 4204 may be used to ensure that the body diode of the transistor 4202 is not rendered conductive when a negative voltage is applied to the terminal T1. This diode 4204 is purely optional, e.g., in case only positive voltages may be applied to the terminal T1. In the embodiment considered, the switch 4202 is closed when the signal SET is asserted and indicates that the switch 400 should be closed, e.g., when the signal SET is high.

In various embodiments, the diode 4204 is an active diode. Generally, an active diode means that the diode is implemented with a FET, wherein the body diode of the FET is used as diode. In fact, in this case, the FET may be driven by a respective control signal. In this case, the FET behaves as a short circuit when the respective control signal has a first logic value, or as a diode when the control signal has a second logic value. For example, in the embodiment considered, such a FET could be driven with the signal SET in order to pull the node T1 to ground without the usual voltage drop of approximately 0.7 V at the diode 4204. Conversely, when the signal SET is low, the FET behaves exactly as the diode 4204 and blocks negative voltages at the node T1.

As mentioned in the foregoing, a similar clamp circuit may also be used for the clamp circuit 422 used to connect the node S to ground (see FIG. 7), e.g., by connecting (e.g., directly) the anode of the diode 4204 to the node S.

Accordingly, a low voltage, e.g., between 1.5 V and 5 V, e.g., 3.0 V or 3.3 V applied to the node G is sufficient to switch on the transistors SW₁ and SW₂. For example, in the embodiment considered, the circuit 412 comprises for this reason an electronic switch 4122, such as a p-channel FET, and a diode 4124 connected in series between the node G and a positive supply voltage VDD_{P}, such as 3.3 V. Specifically, in the embodiment considered, the source of the transistor 4122 is connected (e.g., directly) to the supply voltage VDD_{P}, the drain of the transistor 4122 is connected (e.g., directly) to the anode of the diode 4124 and the cathode of the diode 4124 is connected (e.g., directly) to the node G. Accordingly, when a positive voltage is applied to the gate of the transistor 4122, the transistor 4122 will be opened and the node G will be floating. Conversely, the node G will be connected to the supply voltage VDD_{P} and thanks to the connection of the node S to ground, the node G will be charged, e.g., substantially to VDD_{P} (neglecting the diode 4124). In fact, preferably, also the diode 4124 is an active diode drive as a function of the signal SET, i.e., the diode 4124 behaves as a short circuit, when the signal SET indicates that the switch 400 should be closed.

Accordingly, in the embodiment considered, the switch 4122 should be closed when the signal SET is asserted and indicates that the switch 400 should be closed (e.g., when the signal SET is high). For example, considering the exemplary logic values of the signal SET and the opposed operation of the p-channel FET, the gate of the transistor 4122 may be driven by means of an inverted version of the signal SET. For example, in the embodiment considered, an inverter 4126 is interposed between the terminal SET and the gate of the transistor 4122.

Conversely, FIG. 9 shows an embodiment of the reset circuit 414 configured to discharge the node G, when the signal RESET is asserted and indicates that the switch 400 should be opened (e.g., when the signal RESET is high). Again, as mentioned in the foregoing, the external control circuit generating the signals SET and RESET ensures that the signal RESET tries to close the switch 400 when the drive signal TX applied to the node T1 is deactivated.

In the embodiment considered, in order to switch off the switch 400, the node T1 and/or the node S should be connected to ground GND. As mentioned in the foregoing, this may be ensured directly by the signal generation circuitry 100 and/or by a clamp circuit 420/422 in the switch 400.

For example, in FIG. 9 is used the same clamp circuit 420 already shown in FIG. 8. However, in this case, the clamp circuit 420 should also be active when the signal RESET indicates that the switch 400 should be opened. Accordingly, the gate of the transistor 4202 could be driven, e.g., via an OR gate receiving at input the signals SET and RESET.

In the embodiment considered, the circuit 414 used to discharge the node G is implemented with a clamp circuit comprising an electronic switch 4142, such as a n-channel FET, and a diode 4144, preferably an active diode driven by means of the signal RESET, connected in series between the node G and the node S. Specifically, in the embodiment considered, the source of the transistor 4142 is connected (e.g., directly) to the node S, the drain of the transistor 4142 is connected (e.g., directly) to the cathode of the diode 4144 and the anode of the diode 4144 is connected (e.g., directly) to the node G. Accordingly, when a positive voltage is applied to the gate of the transistor 4142, the transistor 4142 will be closed and the node G is connected to the node S. For example, considering the exemplary logic levels of the signal RESET, the gate of the transistor 4142 may be driven directly by the signal RESET.

Accordingly, when a positive voltage is applied to the gate of the transistor 4142, the transistor 4142 will be closed and the node G will be connected to the node S and the node G will be discharged. Considering the connection of the node S to ground, the node G will thus be discharged to substantially 0 V (again neglecting the diode 4144, which preferably is an active diode).

The inventors have observed that this voltage level might not be sufficient, because charge injected into the node G may still increase the gate-source voltage V_{GS} above the threshold voltage of the transistors SW₁ and SW₂, thereby closing the switch 400.

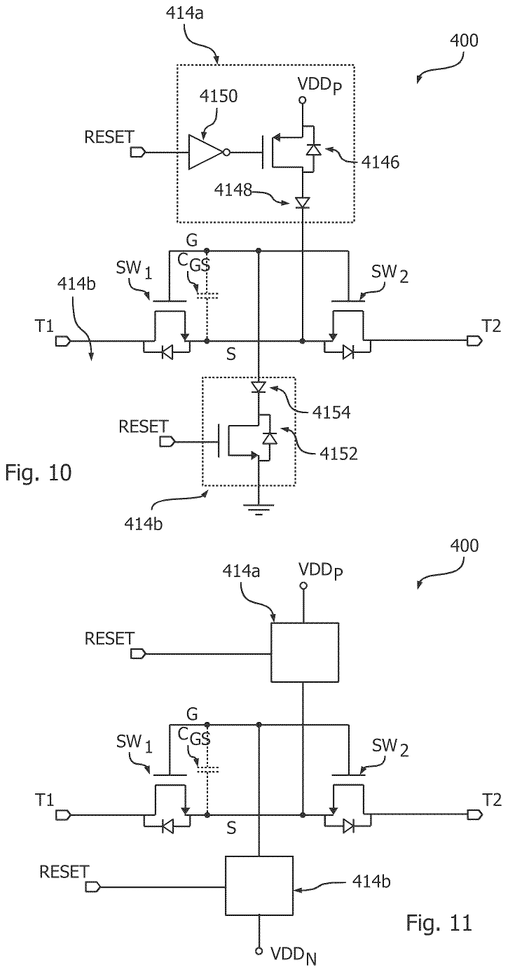

FIG. 10 shows in this regard an alternative embodiment of the circuit 414, in which a negative gate-source voltage V_{GS} is created. In the embodiment considered, the circuit 414 comprises two sub-circuits 414a and 414b.

Specifically, the first sub-circuit 414a is configured to apply a positive voltage to the node S when the signal RESET indicates that the switch 400 should be opened. For example, in the embodiment considered, the circuit 414a has the same architecture as the circuit 412 described with respect to FIG. 8, with the only difference that the circuit is connected to the node S and not the node G. Specifically, in the embodiment considered, an electronic switch 4146, such as a p-channel FET, and a diode 4148, preferably an active diode driven by means of the signal RESET, are connected in series between a positive supply voltage, e.g., VDD_{P}, and the node S, wherein the gate of the transistor 4146 is driven as a function of the signal RESET. For example, in the embodiment considered, an inverter 4150 is used to generate the drive signal applied to the gate of the transistor 4146, i.e., the supply voltage VDD_{P} is applied to the node S when the signal RESET is high.

Conversely, a second circuit 414b is used to connect the node G to ground when the signal RESET indicates that the switch 400 should be opened. For example, in the embodiment considered, the circuit 414a has the same architecture as the clamp circuit 420 described with respect to FIG. 8, with the only difference that the circuit is connected to the node G and not the terminal T1. Specifically, in the embodiment considered, an electronic switch 4152, such as an n-channel FET, and a diode 4154, preferably an active diode driven by means of the signal RESET, are connected between the node G and ground GND, wherein the gate of the transistor 4152 is driven as a function of the signal RESET. For example, in the embodiment considered, the signal RESET is applied directly to the gate of the transistor 4152, i.e., the node G is connected to ground when the signal RESET is high.

Accordingly, in this embodiment, a negative gate-source voltage V_{GS} (approximately −VDD_{P}) will be generated when the signal RESET indicates that the switch 400 should be opened.

As shown in FIG. 11, generally, the circuit 414 may thus comprise two-sub-circuits. The first sub-circuit 414a is configured to selectively apply a first voltage VDD_{P} to the node S when the signal RESET is asserted and indicates that the switch 400 should be opened. The second sub-circuit 414b is configured to selectively apply a second voltage VDD_{N} to the node G when the signal RESET is asserted and indicates that the switch 400 should be opened.

In the embodiment shown in FIG. 9, the voltages VDD_{P} and VDD_{N} are the same and the gate-source voltage is 0 V. Conversely, in the embodiment shown in FIG. 10, the voltage VDD_{P} is greater than the voltage VDD_{N}, thereby generating a negative gate-source voltage:

$${V}_{GS} = {V D D}_{N} - {V DD}_{P} .$$

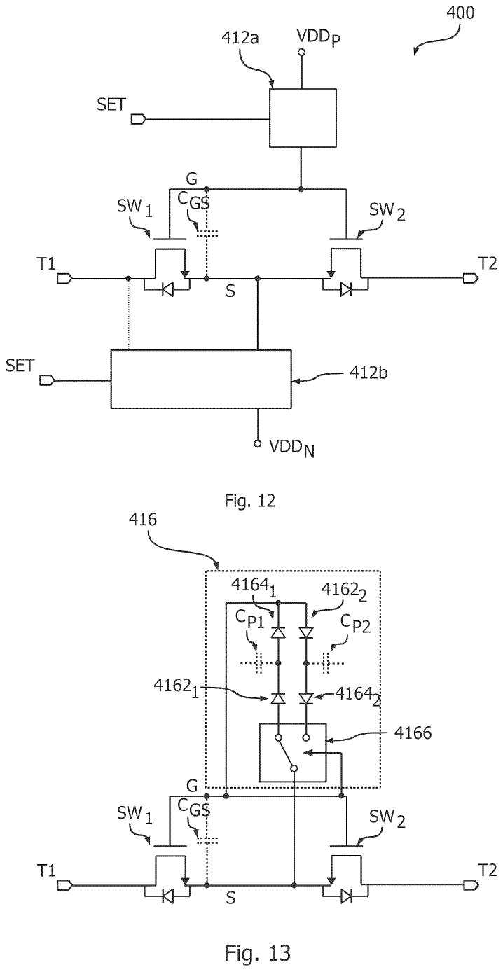

Generally, as shown in FIG. 12, the opposed behavior may be used for the circuit 412, i.e., the circuit 412 may thus comprise two-sub-circuits. The first sub-circuit 412a is configured to selectively apply a first voltage VDD_{P} to the node G when the signal SET is asserted and indicates that the switch 400 should be closed. The second sub-circuit 412b is configured to selectively apply a second voltage VDD_{N} to the node S when the signal SET is asserted and indicates that the switch 400 should be closed. Specifically, the second sub-circuit 412b may apply the second voltage VDD_{N} to the node S directly, as shown, e.g., with respect to the clamp circuit 422 (representing the circuit 412b in FIG. 7), or indirectly via the terminal T1 (or T2), as shown, e.g., with respect to the clamp circuit 420 (representing the circuit 412b in FIGS. 6 and 8). Generally, the voltage VDD_{P} should be greater than the voltage VDD_{N}, thereby generating a positive gate-source voltage:

$${V}_{GS} = {V D D}_{P} - {V DD}_{N} .$$

For example, in the embodiment shown in FIGS. 6, 7 and 8, the voltage VDD_{N} corresponds indeed to ground GND and V_{GS}=VDD_{P}. Generally, the circuits 412 and 414 may also operate with different voltages VDD_{P} and VDD_{N}.

Accordingly, in various embodiments, the set circuit 412 charges the gate-source capacitance C_{GS} and generates a positive gate-source voltage V_{GS} when the signal SET is asserted (e.g., high) indicating that the switch 400 has to be closed. Conversely, the reset circuit 414 discharges the gate-source capacitance C_{GS} and generates a negative gate-source voltage V_{GS} when the signal RESET is asserted (e.g., high) indicating that the switch 400 has to be opened. Accordingly, the gate-source voltage V_{GS} may have two levels: a positive voltage (switch 400 closed), or either a zero voltage or preferably a negative voltage (switch 400 opened).

Finally, the node G is disconnected, i.e., not connected to a supply voltage, when the signals SET and RESET are de-asserted (e.g., both signals are set to low). Accordingly, as disclosed in document U.S. Pat. No. 10,177,759 B1, when the signals SET and RESET have the second logic values (e.g., low), the gate-source capacitance will be discharged due to leakage and/or charge sharing with parasitic capacitance. Moreover, positive and negative charge may be injected into the gate node G through the gate-drain capacitances of the switches SW₁ and SW₂.

Accordingly, in various embodiments, the switching state is periodically reprogrammed via the signals SET and RESET, and/or the circuit 410 comprises also a maintenance circuit 416 configured to inject charge into the gate node G in order to maintain the state of the switch 400 thanks to the oscillation at the node T1 and/or T2.

FIG. 13 shows in this respect a first embodiment of the maintenance circuit 416. Specifically, in the embodiment considered, the maintenance circuit 416 comprises two branches and an electronic switch 4166 configured to connect one of the branches between the nodes G and S. Specifically, each of the branches comprises two diodes connected in series, i.e., diodes 4162₁ and 4164₁ for the first branch and diodes 4162₂ and 4164₂ for the second branch. Generally, also a series connection of more diodes may be used for the diodes 4162 and 4164.

More specifically, in the embodiment considered, the cathode of the diode 4164₁ is connected (e.g., directly) to the node G, the anode of the diode 4164₁ is connected (e.g., directly) to the cathode of the diode 4162₁ and the anode of the diode 4164₁ is connected to the switch 4166 and may thus be connected selectively to the node S. Conversely, the anode of the diode 4162₂ is connected (e.g., directly) to the node G, the cathode of the diode 4162₂ is connected (e.g., directly) to the anode of the diode 4164₂ and the cathode of the diode 4164₂ is connected to the switch 4166 and may thus be connected selectively to the node S.

Accordingly, the first branch defines a conductive path from the node S to the node G (with the opposite direction being blocked, i.e., non-conductive) and the second branch defines a conductive path from the node G to the node S (with the opposite direction being blocked), wherein one of the branches may be activated selectively via the switch 4166.

Moreover, in the embodiment considered, the switch 4166 is driven as a function of the state of the switch 400 (on/off), for example as a function of the signals SET/RESET or the gate-source voltage V_{GS}. Specifically, when the switch 400 is closed (high gate-source voltage V_{GS}), the diodes 4162₁ and 4164₁ are connected between the nodes G and S. Conversely, when the switch 400 is opened (low gate-source voltage V_{GS}), the diodes 4162₂ and 4164₂ are connected between the nodes S and G.

Generally, a parasitic capacitance C_{P1} is associated with the node between the diodes 4162₁ and 4164₁ and a parasitic capacitance C_{P2} is associated with the node between the diodes 4162₂ and 4164₂. In various embodiments, these capacitances are increased voluntarily during the design process of the switch 400 and may be, e.g., between 100 fF (Femto-Farad) and several pF (Pico-Farad).

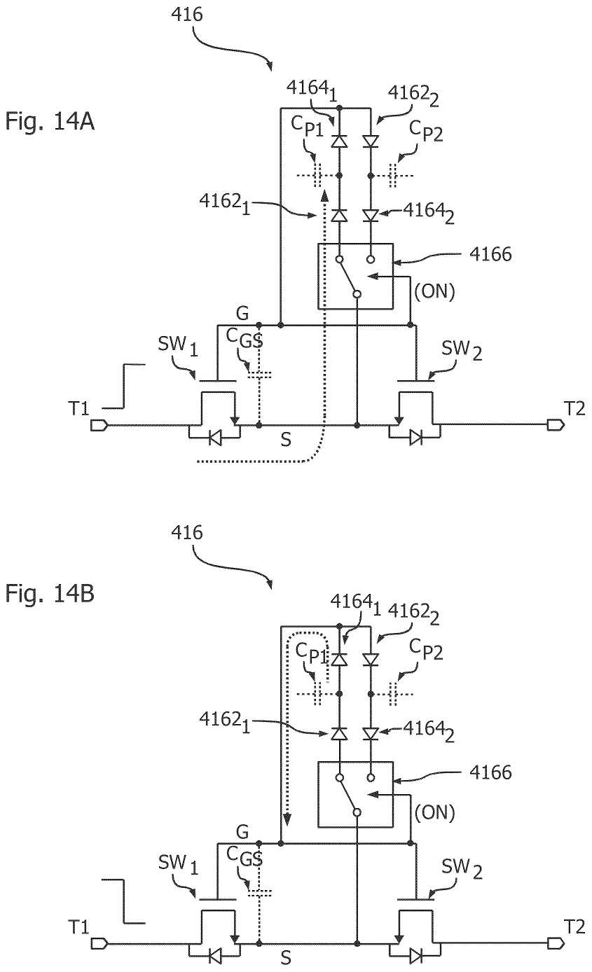

Accordingly, as shown in FIG. 14A, when the switch 400 is closed (ON), positive transitions at the terminal T1 (or T2) may be partially transferred through the diode 4162₁ to the capacitance C_{P1}, thereby charging the capacitance C_{P1} approximately to the voltage at the node T1. For example, assuming a forward voltage of 0.7 V for the diode 4162₁, the capacitance C_{P1} will be charged to approximately 99.3 V for a maximum voltage of 100 V at the node T1. Conversely, the node G will have a higher voltage, e.g., 103.3 V, because the gate-source capacitance C_{GS} maintains the voltage difference. Accordingly, the diode 4164₁ blocks a discharging of the node G to the capacitance C_{P1} during this phase. Moreover, also the second branch comprising the diodes 4162₂ and 4164₂ is disconnected via the switch 4166.

Conversely, as shown in FIG. 14B, when a negative transition occurs, the voltage at the node G will decrease. For example, assuming a minimum voltage of 0 V at the node T1, the voltage at the node G would decrease, e.g., to 3.3 V. Accordingly, the diode 4164₁ will become conductive and the charge at the capacitance C_{P1} will be transferred in part to the node G, thereby charging the gate-source capacitance C_{GS}.

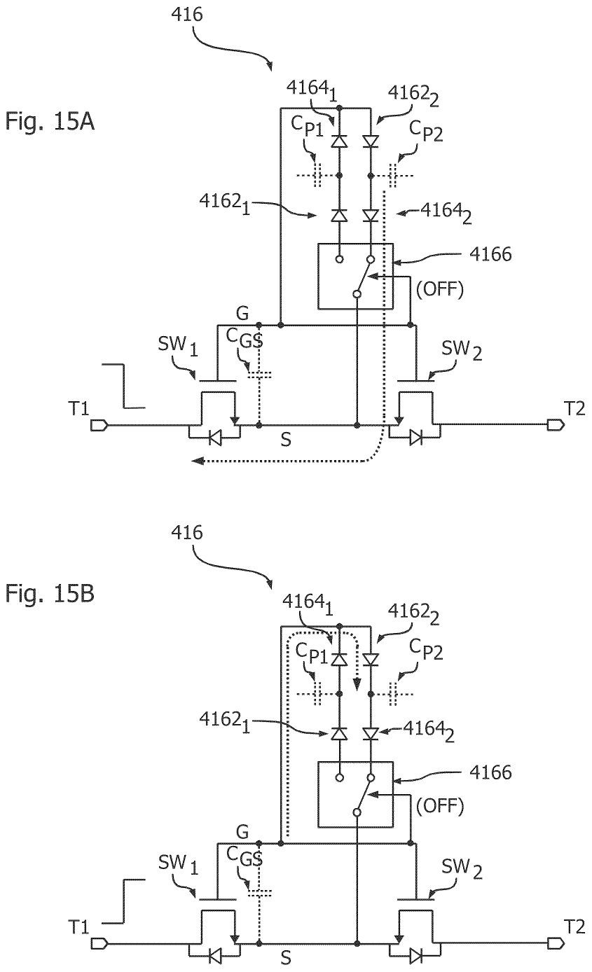

Conversely, as shown in FIGS. 15A and 15B the opposite behavior may be used to discharge the gate-source capacitance C_{GS} via the second branch, i.e., the diodes 4162₂ and 4164₂, when the switch 400 is opened (OFF).

Specifically, as shown in FIG. 15A, when the switch 400 is opened (OFF), negative transitions at the terminal T1 may be used to discharge the capacitance C_{P2} through the diode 4164₂.

Conversely, as shown in FIG. 15B, when a positive transition occurs, the voltage at the node G will increase and the diode 4162₂ will become conductive, thereby discharging the gate-source capacitance C_{GS} to the capacitance C_{P2}.

Document U.S. Pat. No. 10,177,759 B1 also discloses further embodiments of the maintenance/rectification circuit 416, and which is incorporated herein by reference for this purpose. Substantially, these maintenance/rectification circuits are configured to determine whether the switch 400 is on, i.e., when the gate-source voltage V_{GS} is high, or off, i.e., when the gate-source voltage V_{GS} is low. In response to determining that the switch 400 is on, i.e., when the gate-source voltage V_{GS} is high, the maintenance/rectification circuit is configured to, when a positive transition is applied to the node T1, transfer charge from the node S to a capacitance C_{P}/C_{P1}, while inhibiting a transfer of charge from the node G to the capacitance C_{P}/C_{P1}. Conversely, when a negative transition is applied to the node T1, the maintenance/rectification circuit is configured to transfer charge from the capacitance C_{P}/C_{P1} to the node G. Instead, in response to determining that the switch 400 is off, i.e., when the gate-source voltage V_{GS} is low, the maintenance/rectification circuit is configured to, when a negative transition is applied to the node T1, transfer charge from the capacitance C_{P}/C_{P2} to the node S, while inhibiting a transfer of charge from the node G to the capacitance C_{P}/C_{P2}. Conversely, when a positive transition is applied to the node T1, the maintenance/rectification circuit is configured to transfer charge from the node G to the capacitance C_{P}/C_{P2}.

Specifically, in various embodiments, the maintenance circuit 416 is implemented with a rectification circuit comprising for this purpose a switching circuit (e.g., 4166). When the switch 400 is on, i.e., when the gate-source voltage V_{GS} is high, the switching circuit is configured to connect two diodes 4162 and 4164 between the node G and the node S, wherein the diodes 4162 and 4164 are connected in cascade (i.e., the anode of the second diode 4164 is connected to the cathode of the first diode 4162), and wherein a capacitance C_{P}/C_{P1} is associated with the intermediate point between the diodes 4162/4164, such that a conductive path is created permitting a current flow only from the node S to the node G. Conversely, when the switch 400 is off, i.e., when the gate-source voltage V_{GS} is low, the switching circuit is configured to connect two diodes 4162 and 4164 between the node S and the node G, wherein the diodes 4162 and 4164 are connected in cascade (i.e., the anode of the second diode 4164 is connected to the cathode of the first diode 4162), and wherein a capacitance C_{P}/C_{P2} is associated with the intermediate point between the diodes 4162/4164, such that a conductive path is created permitting a current flow only from the node G to the node S.

In various embodiments, the maintenance/rectification circuit 416 comprises two separate branches of diodes and a switching circuit configured to enable one of these branches (see, e.g., FIG. 13). However, as described in document U.S. Pat. No. 10,177,759 B1, the maintenance/rectification circuit 416 may also comprise a single branch of diodes and a switching circuit configured to change the orientation of this branch between the nodes G and S. In various embodiments, also these diodes may be active diodes.

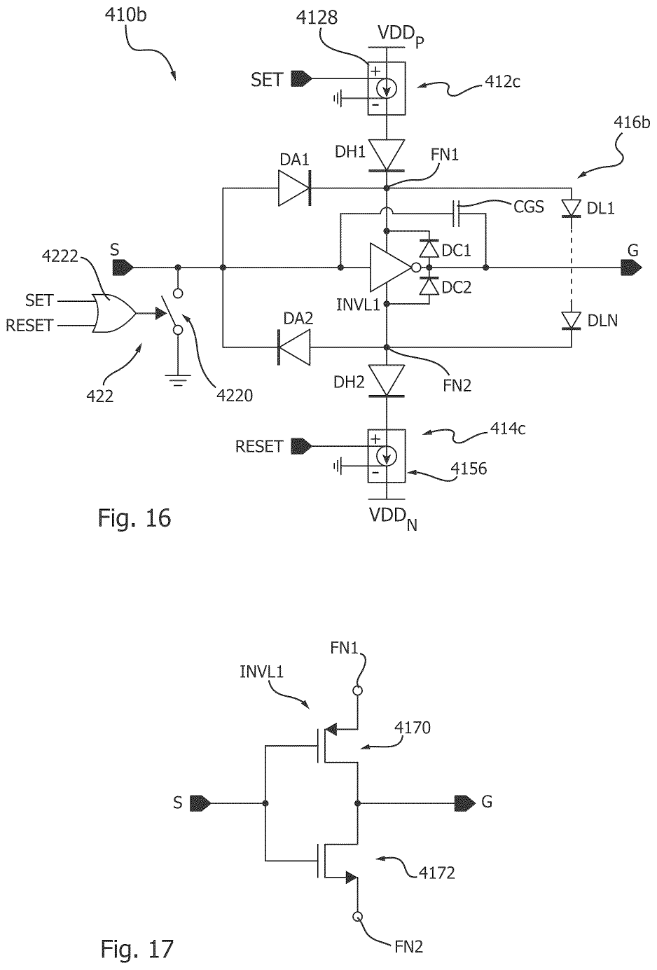

FIG. 16 shows a further embodiment of a control circuit 410b comprising a clamping circuit 422, a set circuit 412c, a reset circuit 414c and a maintenance circuit 416b.

Specifically, in the embodiment considered, the maintenance circuit 416b comprises a plurality of diodes. Specifically, in the embodiment considered, a diode DA1 is connected (e.g., directly) between the node S and a node FN1, wherein the anode of the diode DA1 is connected to the node S and the cathode of the diode DA1 is connected to the node FN1. A diode DA2 is connected (e.g., directly) between a node FN2 and the node S, wherein the anode of the diode DA2 is connected to the node FN2 and the cathode of the diode DA2 is connected to the node S. Moreover, a given number N of diodes DL1 to DLN, with N>1, are connected in cascade between the node FN1 and the node FN2, wherein the anode of the (first) diode DL1 is connected to the node FN1 and the cathode of the (last) diode DLN is connected to the node FN2. Possible intermediate diodes between the diodes DL1 and DLN have the anode connected to an upstream diode, e.g., the anode of diode DL2 is connected to the cathode of diode DL1, and the cathode connected to a downstream diode, e.g., the cathode of diode DL2 is connected to the anode of diode DL3.

Moreover, the maintenance circuit 416b comprises a logic inverter INVL1, wherein an input of the inverter INVL1 is connected (e.g., directly) to the node S, and an output of the inverter INVL1 is connected (e.g., directly) to the node G. Specifically, the inverter INVL1 is supplied with the voltage between the nodes FN1 and FN2, i.e., the voltage at the diodes DL1 to DLN. In various embodiments, at least part of the diodes DL1 to DLN may also be replaced with a Zener diode, e.g., a Zener diode having a cathode connected to the node FN1 and an anode connected to the node FN2. Thus, when referring to the voltage drop at the diodes DL1 to DLN, this voltage drop may be equally obtained via one or more Zener diodes.

Substantially, as will be described in greater detail in the following, the inverter INVL1 is configured to maintain the charge of the capacitance C_{GS} between the nodes G and S.

In general, the logic inverter INVL1 may be implemented in any suitable way. For example, FIG. 17 shows an embodiment, wherein the inverter comprises a p-channel FET 4170 and a n-channel FET 4172 connected in series between the nodes FN1 and FN2. Specifically, in the embodiment considered, the source terminal of the p-channel FET 4170 is connected (e.g., directly) to the node FN1, the drain terminal of the p-channel FET 4170 is connected (e.g., directly) to the node G and the gate terminal of the p-channel FET 4170 is connected (e.g., directly) to the node S. Conversely, the source terminal of the n-channel FET 4172 is connected (e.g., directly) to the node FN2, the drain terminal of the n-channel FET 4172 is connected (e.g., directly) to the node G, i.e., the drain terminal of the p-channel FET 4170, and the gate terminal of the n-channel FET 4172 is connected (e.g., directly) to the node S, i.e., the gate terminal of the p-channel FET 4170.

Moreover, in various embodiments, the maintenance circuit 416b comprises a clamping circuit for the node G. Specifically, in the embodiment considered, a diode DC1 is connected between the node G and the node FN1, wherein the anode of the diode DC1 is connected to the node G and the cathode of the diode DC1 is connected to the node FN1. Moreover, in the embodiment considered, a diode DC2 is connected between the node FN2 and the node G, wherein the anode of the diode DC2 is connected to the node FN2 and the cathode of the diode DC2 is connected to the node G. In various embodiments, the diodes DC1 and DC2 can be also the intrinsic diode of the FETs 4170 and 4172.

In various embodiments, the clamping circuit 422 is again used to connect the node S to ground when the set signal SET or reset signal RESET are asserted. For example, in the embodiment considered, the clamping circuit 422 comprises an electronic switch 4220 (having a current path) connected between the node S and ground. Moreover, a logic gate 4222, such as an OR gate, is configured to generate the drive signal for the electronic switch 4220 by combining the signals SET and RESET, wherein the electronic switch 4220 is closed when the signal SET or the signal RESET is asserted, and the electronic switch 4220 is opened when the signal SET and the signal RESET are de-asserted.

In the embodiment considered, instead of directly charging the capacitance C_{GS}, the set circuit 412c comprises a current source 4128 and a diode DH1 (essentially implementing the function of the diode 4124 shown in FIG. 8) connected in series between the voltage VDD_{P} and the node FN1. Specifically, the cathode of the diode DH1 is connected (e.g., directly) to the node FN1 and the anode of the diode DH1 is connected via the current source 4128 to the supply voltage VDD_{P}, wherein the current source 4128 is enabled when the set signal SET is asserted.

Similarly, in the embodiment considered, instead of directly discharging the capacitance C_{GS}, the reset circuit 414c comprises a current source 4156 and a diode DH2 (essentially implementing the function of the diode 4154 shown in FIG. 10) connected in series between the node FN2 and the voltage VDD_{N}. Specifically, the anode of the diode DH2 is connected (e.g., directly) to the node FN2 and the cathode of the diode DH2 is connected via the current source 4156 to the supply voltage VDD_{N}; wherein the current source 4156 is enabled when the reset signal RESET is asserted.

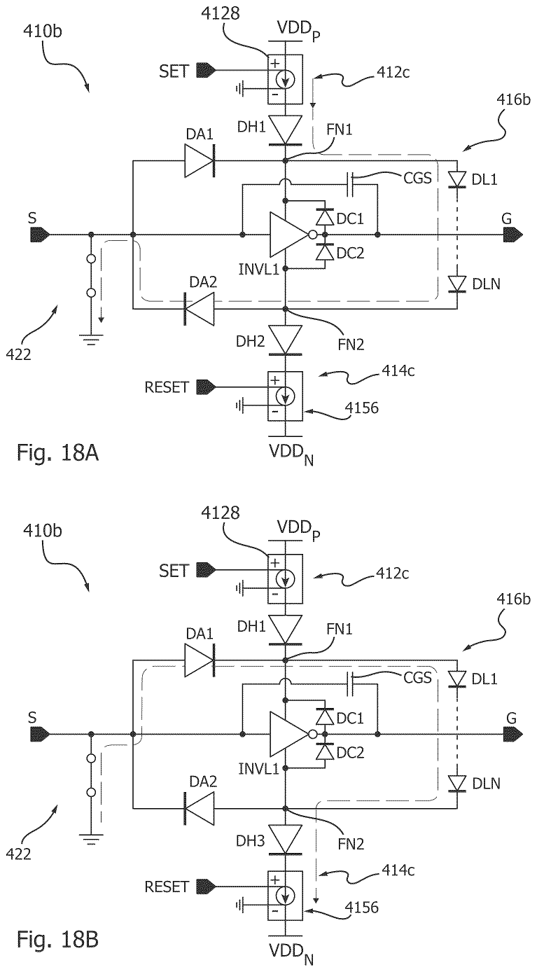

FIGS. 18A and 18B show the set and reset phases, respectively, of the control circuit 410b shown in FIG. 16.

Specifically, as shown in FIG. 18A, in response to determining that the set signal SET is asserted, the clamping circuit 422 connects the node S to ground, i.e., the voltage at the node S is approximately 0V.

Moreover, in response to determining that the set signal SET is asserted, the current source 4128 applies a current via the diode DH1 to the node FN1. Specifically, assuming that the diodes DA1, DA2 and DL1 to DLN have the same forward voltage Va, this current flow provided by the current source 4128 generates at the node FN2 a voltage Va (via the diode DA2), and at the node FN1 a voltage (N+1)·V_{d}, i.e., the sum of the voltage drops at the diodes DA2 and DL1 to DLN, wherein the voltage between the nodes FN1 and FN2 corresponds to N. V.

Accordingly, also considering the voltage drop at the diode DH1, the supply voltage VDD_{P} should be higher than (N+2). Va, or vice versa, the number N of diodes DL1 to DLN should be smaller than [(VDD_{P}/V_{d},)−2]. Accordingly, in this condition, the voltage at the input of the inverter INVL1, i.e., the difference between the voltage at the node S and the voltage at the node FN2, is negative and the inverter INVL1 connects the output of the inverter INVL1, i.e., the node G, to the node FL1, whereby the voltage at the node G corresponds to the voltage at the node FL1. Accordingly, in this condition, the node G is at a positive voltage with respect to the node S and the transistors SW₁ and SW₂ are closed, i.e., the switching circuit 400 is closed/conductive. Specifically, in this condition, the voltage at the capacitance C_{GS}, also indicated as voltage V_{GSon} in the following, corresponds to (N+1)·V_{d}.

Specifically, as shown in FIG. 18B, in response to determining that the reset signal RESET is asserted, the clamping circuit 422 connects the node S to ground, i.e., the voltage at the node S is approximately 0V.

Moreover, in response to determining that the reset signal RESET is asserted, the reset circuit applies a current via the diode DH2 to the node FN2. Specifically, again assuming that the diodes DA1, DA2 and DL1 to DLN have the same forward voltage Va, this current flow provided by the current source 4156 generates at the node FN1 a voltage −V_{d} (via the diode DA1), and at the node FN2 a voltage −(N+1)·V_{d}, i.e., the sum of the voltage drops at the diodes DA1 and DL1 to DLN. Accordingly, also considering the voltage drop at the diode DH2, the supply voltage VDD_{N} should be smaller than −(N+2)·V_{d}, or vice versa, the number N of diodes should be smaller than [(−VDD_{N}/V_{d})−2]. For example, in various embodiments the (positive) voltage VDD_{P} and the (negative) voltage VDD_{N} have (approximately) the same amplitude, but opposite signs, e.g., VDD_{N}=−VDD_{P}. Accordingly, in this condition, the voltage at the input of the inverter INVL1, i.e., the difference between the voltage at the node S and the voltage at the node FN2, is positive and the inverter INVL1 connects the output of the inverter INVL1, i.e., the node G, to the node FL2, whereby the voltage at the node G corresponds to the voltage at the node FL2. Accordingly, in this condition, the node G is at a negative voltage with respect to the node S and the transistors SW₁ and SW₂ are opened, i.e., the switching circuit 400 is opened/non-conductive. Specifically, in this condition, the voltage at the capacitance C_{GS}, also indicated as voltage V_{GSoff} in the following, corresponds to −(N+1)·V_{d}.

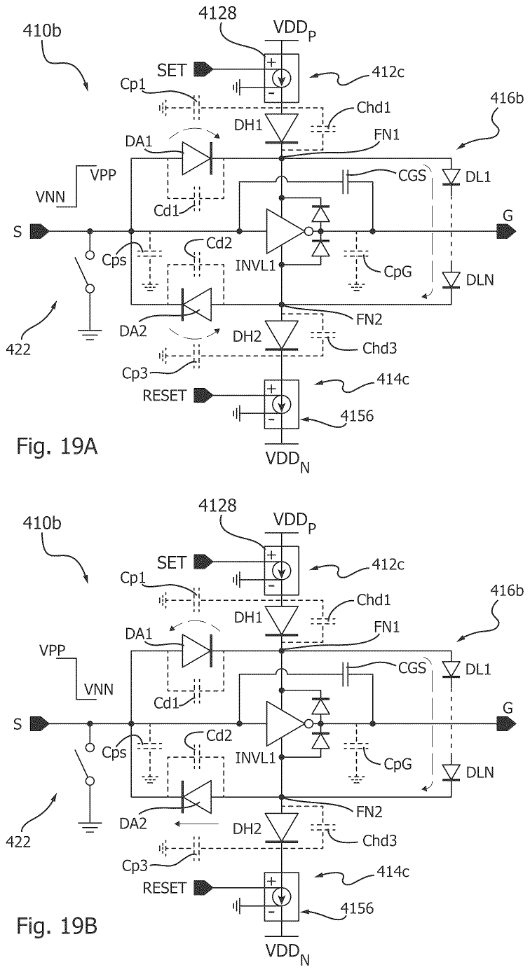

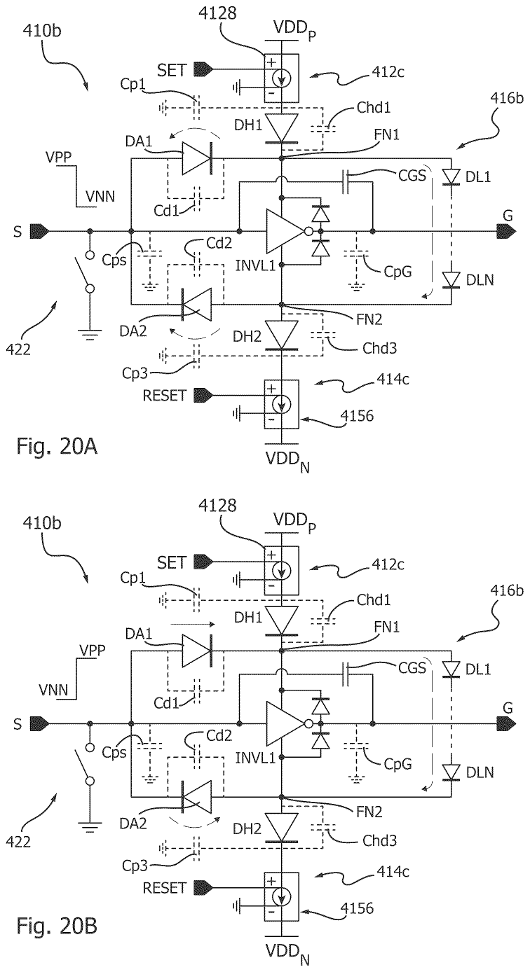

Once having set or reset the voltage at the node G, the signals SET and RESET are de-asserted and the circuit 100 generate the drive signal, which is applied to the node T1 of the switching circuit 400. Specifically, FIGS. 19A and 19B show the behavior of the switching circuit 400, when the switching circuit 400 is closed (as described with respect to FIG. 18A), and FIGS. 20A and 20B show the behavior of the switching circuit 400, when the switching circuit 400 is opened (as described with respect to FIG. 18B). These figures also show typical parasitic capacitances in the circuit, such as a parasitic capacitance CpS associated with the node S, a parasitic capacitance CpG associated with the node G, a parasitic capacitance Cd1, Cd2, Chd1 and Chd2 associated with the diodes DA1, DA2, DH1 and DH2, respectively.

Specifically, FIG. 19A shows the haviour when the switching circuit 400 is closed, i.e., the voltage V_{GS} is positive, and a positive transition is applied to the node T1, i.e., the voltage at the node T1 increases to a voltage VPP, which is also applied to the node S, because the transistor SW₁ is closed. Specifically, due to the capacitance C_{GS}, the voltage at the node G increases to VPP+V_{GSon}, which is also applied to the node FL1 via the inverter INVL1, which connects the node FL1 to the node G. Moreover, due to the diodes DL1 to DLN, the voltage at the node FL2 corresponds to VPP+V_{GSon}−N·V_{d}.

Conversely, FIG. 19B shows the haviour when the switching circuit 400 is closed, i.e., the voltage V_{GS} is positive, and a negative transition is applied to the node T1, i.e., the voltage at the node S decreases to a voltage VNN, which is also applied to the node S, because the transistor SW₁ is closed. Specifically, in this case, the diode DA2 becomes conductive, whereby the voltage at the node FL2 corresponds to VNN+V_{d}. Accordingly, the voltage at the node FL1 corresponds to VNN+V_{d}+N·V_{d}, thereby recharging the capacitance C_{GS}.

FIG. 20A shows the haviour when the switching circuit 400 is opened, i.e., the voltage V_{GS} is negative, and a negative transition is applied to the node T1, which is also applied to the node S, because the body diode of the transistor SW₁ is closed. Specifically, due to the capacitance C_{GS}, the voltage at the node G decreases to VNN+V_{GSoff}, which is also applied to the node FL2 via the inverter INVL1, which connects the node FL2 to the node G. Conversely, the voltage at the node FL1 corresponds to VNN+V_{GSoff}+N·V_{d}.

Conversely, FIG. 20B shows the haviour when the switching circuit 400 is opened, i.e., the voltage V_{GS} is negative, and a positive transition is applied to the node T1, which is also applied to the node S. Specifically, in this case, the diode DA1 becomes conductive, whereby the voltage at the node FL1 corresponds to VNN−V_{d}. Accordingly, the voltage at the node FL2 corresponds to VNN−V_{d}−N·V_{d}, thereby recharging the capacitance C_{GS}.

As mentioned before, such HV-less high voltage switching circuits often imply a possible memory effect, wherein the rise and/or fall times at the node T1 may not be constant.

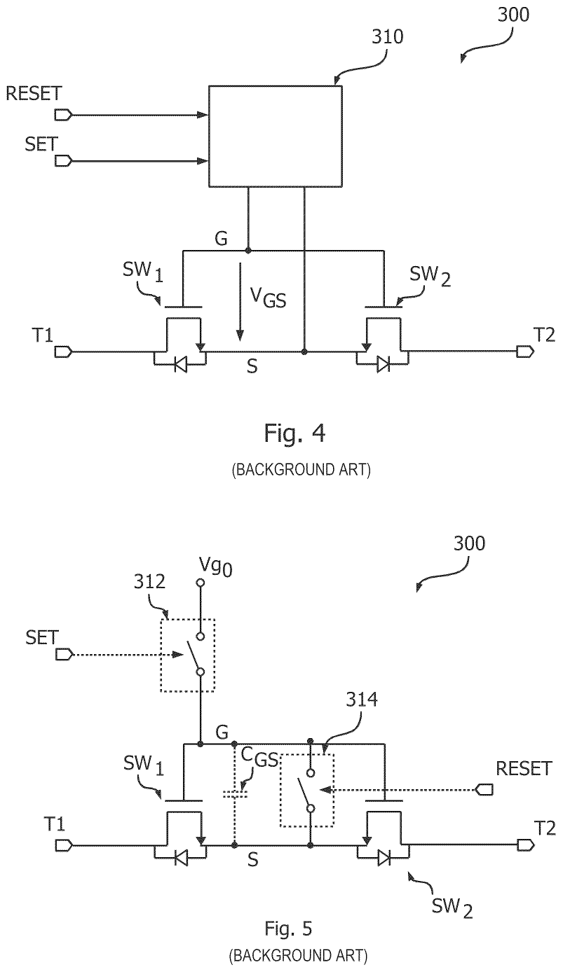

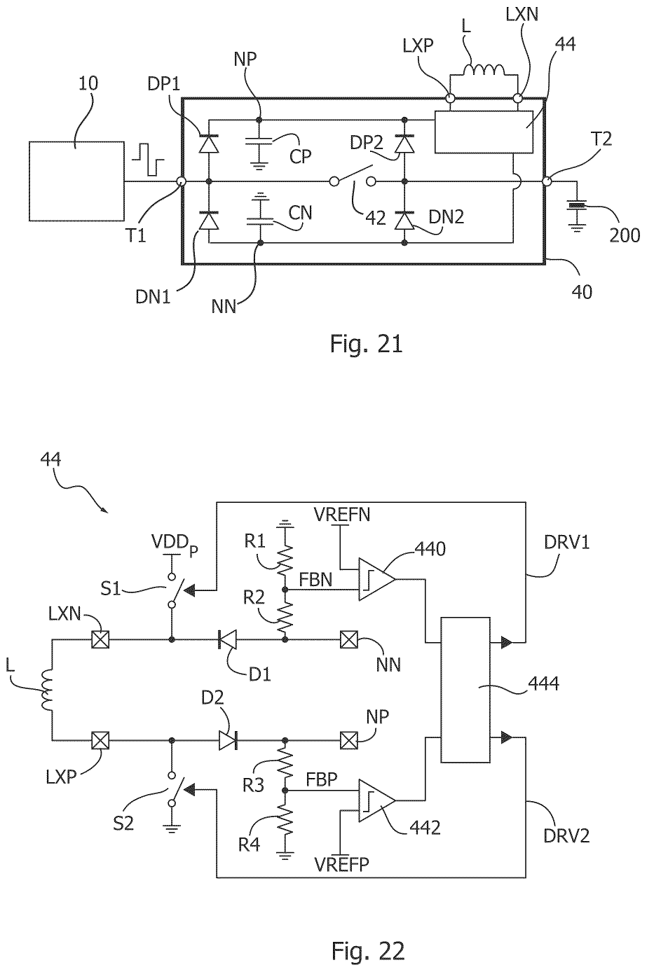

FIG. 21 shows in this respect an embodiment of a switching circuit 40 according to the present application. Specifically, the switching circuit 40 comprises at least one electronic switch 42 connected between two terminals T1 and T2, wherein the electronic switch 42 may be implemented with any of the previously described switching circuits 300 or 400. Accordingly, while FIG. 21 schematically shows a switch 42, indeed this switch 42 comprises (at least) two transistors SW₁ and SW₂ and a respective control circuit, such as respective a control circuit 310 or 410 or 410b as described with respect to FIGS. 4 to 20B.

For example, in various embodiments, the switching circuit 40 is used as the switching circuit 30 shown in FIG. 3, wherein the switching circuit 40 comprises a plurality of electronic switches 42, wherein each electronic switches 42 is configured to connect a respective output terminal T2 to a (common) input terminal T1 as a function of one or more control signals. For example, as shown in FIG. 3, such a switching circuit 40 may be used to connect a plurality of ultrasonic transducers 200 to an ultrasonic system 10, e.g., comprising the circuits 100, 110, 120 and 130 described with respect to FIGS. 1 to 3.

For example, as described before, usually the control signals comprise a set signal SET in order to close the electronic switch 42 and a reset signal RESET in order to open the electronic switch 42. In various embodiments, the set signal SET and the reset signal RST may also be generated internally, e.g., starting from a single control signal. For example, a rising edge of the control signal may be used to assert the set signal SET for a given time period, and a falling edge of the control signal may be used to assert the reset signal RESET for a given time period. In various embodiments, the time periods may be configurable, e.g., programmable.

Accordingly, in various embodiments, the control circuit of the switching circuit 42 comprises a set circuit and a reset circuit. In response to determining that a set signal SET is asserted, the set circuit is configured to set the voltage between the nodes G and S to a first voltage in order to close the transistors SW₁ and SW₂. In response to determining that a reset signal RESET is asserted, the reset circuit is configured to set the voltage between the nodes G and S to a second voltage in order to open the transistors SW₁ and SW₂. Conversely, in various embodiments, when the set signal SET and the reset signal RESET are both de-asserted, the set and reset circuits do not drive the voltage between the nodes G and S, but the node G is floating with respect to the voltage at the node S due to the capacitance C_{GS} between the nodes G and S. As mentioned before, the control circuit may also comprise a maintenance circuit configured to recharge the capacitance between the nodes G and S based on the signal applied to the terminal T1.

Specifically, in various embodiments, the first voltage and the second voltage are small compared to the amplitude of the signal applied to the terminal T1. For example, in various embodiments, the absolute values of the first and second voltage are smaller than 12 V.

However, as mentioned before, the switching circuit 40 may comprise one or more nodes, which are charged via the switching activity at the node T1 (approximately) either to the voltage VPP (maximum value of the signal received at the terminal T1) or to the voltage VNN (minimum value of the signal received at the terminal T1).

For example, in various embodiments, the switching circuit 40 comprises a node NP which should be charged (approximately) to the voltage VPP. For example, for this purpose the switching circuit 40 may comprise a diode DP1, wherein the anode of the diode DP1 is connected to the terminal T1, and the cathode is connected to the node NP. Accordingly, in this way, when applying a pulsed voltage to the terminal T1 oscillating between a minimum voltage VNN and a maximum voltage VPP, a capacitance CP associated with the node NP is charged (approximately) to the voltage VPP. In various embodiments, the capacitance CP corresponds to a parasitic capacitance and/or one or more capacitors connected to the node NP.

Additionally or alternatively, in various embodiments, the switching circuit 40 comprises a node NN which should be charged (approximately) to the voltage VNN. For example, for this purpose the switching circuit 40 may comprise a diode DN1, wherein the cathode of the diode DN1 is connected to the terminal T1 or the node S, and the anode is connected to the node NN. Accordingly, in this way, when applying a pulsed voltage to the terminal T1 oscillating between a minimum voltage VNN and a maximum voltage VPP, a capacitance CN associated with the node NN is charged (approximately) to the voltage VNN. In various embodiments, the capacitance CN corresponds to a parasitic capacitance and/or one or more capacitors connected to the node NN.

For example, in various embodiments, the diodes DP1 and DN1 correspond to electrostatic discharge (ESD) protection diodes for the terminal T1. Similar protection diodes DP2 and DN2 may also be provided for each terminal T2 and/or each node S. For example, in various embodiments, the cathode of the diode DP2 is connected (e.g., directly) to the node NP and the anode of the diode DP2 is connected (e.g., directly) to the terminal T2. Similarly, in various embodiments, the anode of the diode DN2 is connected (e.g., directly) to the node NN and the cathode of the diode DN2 is connected (e.g., directly) to the terminal T2. Accordingly, once the control circuit of the switching circuit 40 is supplied, the capacitances CP and CN are discharged. Next, in response to the set and reset signals SET and RESET, the control circuit sets the state of the electronic switch 42 to closed or opened by using low supply voltages, such as VDD_{P} and VDD_{N}. However, this implies that, once a pulsed signal is applied to the terminal T1, the nodes NP and NN have first to be charged to the maximum values VPP and VNN, respectively. Exactly this charging during the first pulses introduces the previously mentioned memory effect.

In order to reduce or even avoid this problem, in various embodiments, the switching circuit 40 comprises further an electronic converter circuit 44 comprising one or more electronic converters configured to charge the node NP (approximately) to the voltage VPP and/or the node NN (approximately) to the voltage VNN. Accordingly, in this way, when the transmission circuit 100 generates the oscillating signal at the terminal T1, the nodes NP and NN are already pre-charged, thereby avoiding the previously described memory effect.

Specifically, in various embodiments, the one or more electronic converters are configured to generate the (high) voltages VPP and/or VNN based on the (low) voltages VDD_{P} and/or VDD_{N}. In general, any suitable electronic converter topology may be used for generating the voltages VPP and/or VNN. For example, considering that the converters are step-up converters, the circuit 44 may comprise one or more boost or inverting-boost converters. However, also more complex transformer-based converters may be used, such as flyback, forward, or various types of half-bridge or full-bridge converters. For example, such transformer-based converters have the advantage that the transformer may comprise a plurality of secondary windings implementing a multiple-output converter.

However, the inventors have observed that the converter circuit 44 may just be able to charge some nodes and is not required to continuously supply a (large) load. Accordingly, in various embodiments, a low-power and low-complexity solution may be used.

FIG. 22 shows an embodiment of the converter circuit 44. Specifically, in the embodiment considered, the converter circuit comprises a boost converter configured to generate the voltage at the node NP and an inverting buck-boost converter configured to generate the voltage at the node NN.

Specifically, the boost converter comprises an inductance L, such as an inductor. For example, as shown in FIG. 21, the inductance L may be external with respect to an integrated circuit (IC) comprising the other components of the switching circuit 40, i.e., the integrated circuit of the switching circuit 40 may comprise two pads (of an integrated circuit die) or pins (of a packaged IC) for connecting the inductance L to the converter circuit 40. For example, in FIGS. 21 and 22 are shown terminals of nodes LXP and LXN for connecting the inductance L to the converter circuit 40.

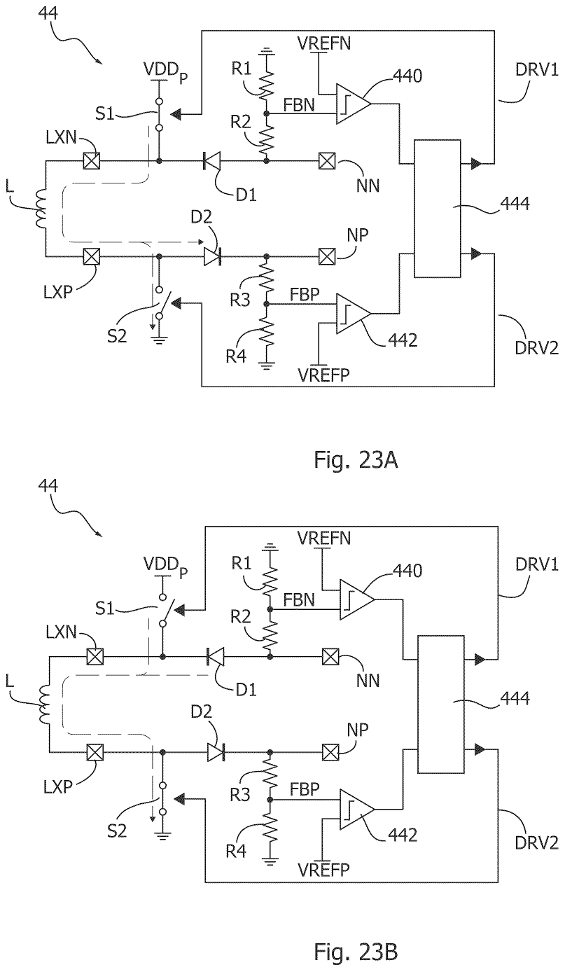

Specifically, in a boost converter, a first terminal of the inductance L, indicated in FIG. 22 as node LXN, is connected to a positive supply voltage, such as VDD_{P}. As will be described in greater detail in the following, in various embodiments, the node LXN is not connected directly to the voltage VDD_{P}, but the node LXN is connected to the voltage VDD_{P} via an electronic switch. For example, FIG. 23A shows an embodiment of the converter circuit 44 in a boost operating mode, i.e., when the node LXN is connected to the supply voltage VDD_{P}.

Specifically, in various embodiments, this electronic switch corresponds to an electronic switch S1 used by the inverting buck-boost converter. In the embodiment considered, the second terminal of the inductance L, indicated in FIG. 22 as node LXP, is connected selectively via (the current path of) an electronic switch S2 to ground GND, and via (the current path of) an electronic switch D2 to the node NP. In various embodiments, the electronic switch D2 is implemented with a diode, wherein the anode of the diode D2 is connected (e.g., directly) to the node LXP and the cathode of the diode D2 is connected (e.g., directly) to the node NP.

In various embodiments, the converter circuit 40 comprises thus also a control circuit 444 configured to generate a drive signal DRV2 for the electronic switch S2, and optionally a drive signal for the electronic switch D2.

In general, a boost converter may be operated in Continuous-Conduction-Mode (CCM) or Discontinuous Conduction Mode (DCM). These modes are well-known in the art.

Substantially, in CCM, the boost converter operates with switching cycles having two switching phases: a switch-on phase where the electronic switch S2 is closed and the electronic switch D2 is opened, and a switch-off phase where the electronic switch S2 is opened and the electronic switch D2 is closed. Specifically, assuming that the node LXN is connected either directly to the voltage VDD_{P} or the switch S1 is closed, the current flowing through the inductance L increases substantially linearly during the switch-on phase, because the inductance is connected between VDD_{P} and ground GND. Conversely, during the switch-off phase, the current flowing through the inductance L is now provided to the node NP, thereby charging the capacitance CP associated with the node NP. In various embodiments, the capacitance CP may also comprise capacitors connected externally to the IC of the switching circuit 40. During this phase, the current flowing through the inductance L decreases substantially linearly.

Conversely, in DCM, the switch off phase has indeed two sub-phases. In the first sub-phase the electronic switch D2 is closed and the current flowing through the inductance L decreases. However, once the current flowing through the inductance L reaches zero, the second sub-phase is started by opening also the electronic switch D2. For example, this may be implemented automatically when the electronic switch D2 is a diode, or the control circuit 444 may be configured to measure a signal indicative of the current flowing through the inductance L and open the electronic switch D2 in response to determining that current flowing through the inductance L reaches zero.

Accordingly, as well-known in the art, the energy transfer to the node NP may be regulated by varying the duration of the switch-on and/or switch-off phases.

For example, in various embodiments, the drive signal DRV2 is a Pulse-Width-Modulated signal, wherein the converter circuit is configured to vary the duty cycle of the drive signal DRV2 in order to regulate the voltage at the node NP (approximately) to the voltage VPP. For example, for this purpose, the control circuit 444 may measure the voltage at the node NP and compare the voltage with a reference voltage. For example, in the embodiment considered, the boost converter comprises a measurement circuit, such as a voltage divider comprising two resistances, e.g., resistors, R3 and R4, configured to provide a feedback signal FBP being indicative of (and preferably proportional to) the voltage at the node NP. Moreover, the boost converter comprises an error amplifier 442 configured to generate a signal indicative of a requested duty-cycle of the signal DRV2 by comparing the feedback signal FBP with a reference signal, such as a reference voltage VREFP, indicative of a requested value for the feedback signal FBP, and thus requested value for the voltage at the node NP. For example, typically the error amplifier implements a regulator comprising an integral (I) component, and optionally a proportional (P) and/or derivate (D) component. While the error amplifier 442 is shown separately, this error amplifier may also be implemented in the control circuit 444. Accordingly, in this case, the control circuit 444 is configured to generate the PWM drive signal DRV2 having a duty-cycle as indicated by the signal at the output of the error amplifier 442.

Conversely, for low-power applications, the boost converter may be driven with a burst mode. Specifically, in this case, the control circuit 444 may be configured to determine whether the feedback signal FBP is smaller than a lower threshold. In response to determining that the feedback signal FBP is smaller than the lower threshold, the control circuit 444 may generate pulses in the drive signal DRV2 until the control circuit 444 determines that the feedback signal FBP becomes greater than an upper threshold.

In various embodiments, also the inverting buck-boost converter comprises an inductance L, such as an inductor. Specifically, in FIG. 22, the boost and the inverting buck-boost converter use the same inductance L, but the converters may also be independent and may use independent inductances. Accordingly, in various embodiments, also the inductance L of the inverting buck-boost converter may be external with respect to an integrated circuit (IC).

Specifically, in an inverting buck-boost converter, a first terminal of the inductance L, indicated in FIG. 22 as node LXN, is connected selectively via an electronic switch S2 to a positive supply voltage, such as VDD_{P}, and via an electronic switch D1 to the node NN. For this reason, the electronic switch S2 may also be used in the boost converter in order to connect the node LXN to the supply voltage VDD_{P}. In the embodiment considered, the second terminal of the inductance L, indicated in FIG. 22 as node LXP, is connected to ground GND. In various embodiments, the node LXP is not connected directly to the ground GND, but the node LXN is connected to ground via an electronic switch. Specifically, in various embodiments, this electronic switch corresponds to the electronic switch S2 used by boost converter, which is already connected between the node LXP and ground. In this respect, FIG. 23B shows an embodiment of the converter circuit 44 in an inverting buck-boost operating mode, i.e., when the node LXP is connected to ground. In various embodiments, the electronic switch D1 is implemented with a diode, wherein the anode of the diode D1 is connected (e.g., directly) to the node NN and the cathode of the diode D1 is connected (e.g., directly) to the node LXN.

In various embodiments, the control circuit 444 is configured to generate also a drive signal DRV1 for the electronic switch S1, and optionally a drive signal for the electronic switch D1.

More specifically, in various embodiments, the boost and the inverting buck-boost converter are combined and use the same inductance L. Specifically, in this case, the control circuit 444 may be configured to use the boost converter mode (FIG. 23A) and the inverting buck-boost converter mode (FIG. 23B). Specifically, in the boost converter mode, the control circuit 444 sets the drive signal DRV1 in order to close the electronic switch S1, and generates the drive signal DRV2 for the electronic switch S2 and optionally the drive signal for the electronic switch D2 in order to regulate the voltage at the node NP. Conversely, in the inverting buck-boost converter mode, the control circuit 444 sets the drive signal DRV2 in order to close the electronic switch S2, and generates the drive signal DRV1 for the electronic switch S1 and optionally the drive signal for the electronic switch D1 in order to regulate the voltage at the node NN.

In general, also an inverting buck-boost converter may be operated in CCM and DCM.

Substantially, in CCM, the inverting buck-boost converter operates with switching cycles having two switching phases: a switch-on phase where the electronic switch S1 is closed and the electronic switch D1 is opened, and a switch-off phase where the electronic switch S1 is opened and the electronic switch D1 is closed. Specifically, assuming that the node LXP is connected either directly to ground GND or the switch S2 is closed, the current flow through the inductance L increases substantially linearly during the switch-on phase, because the inductance is connected between VDD_{P} and ground GND. Conversely, during the switch-off phase, the current flowing through the inductance L is now connected (with opposed sign) to the node NN, thereby discharging the capacitance CN associated with the node NN. In various embodiments, the capacitance CN may also comprise capacitors connected externally to the IC of the switching circuit 40. During this phase, the current flowing through the inductance L decreases substantially linearly, but generates a negative voltage at the node NN.

Conversely, in DCM, the switch off phase has indeed two sub-phases. In the first sub-phase the electronic switch D1 is closed and the current flowing through the inductance L decreases. However, once the current flowing through the inductance L reaches zero, the second sub-phase is started by opening also the electronic switch D1. For example, this may be implemented automatically when the electronic switch D1 is a diode, or the control circuit 444 may be configured to measure a signal indicative of the current flowing through the inductance L and open the electronic switch D1 in response to determining that current flowing through the inductance L reaches zero.

Also in this case, the energy transfer to the node NN may be regulated by varying the duration of the switch-on and/or switch-off phases.

For example, in various embodiments, the drive signal DRV1 is a Pulse-Width-Modulated signal, wherein the converter circuit is configured to vary the duty cycle of the drive signal DRV1 in order to regulate the voltage at the node NN (approximately) to the voltage VNN. For example, for this purpose, the control circuit may measure the voltage at the node NN and compare the voltage with a reference voltage. For example, in the embodiment considered, the inverting buck-boost converter comprises a measurement circuit, such as a voltage divider comprising two resistances, e.g., resistors, R1 and R2, configured to provide a feedback signal FBN being indicative of (and preferably proportional to) the voltage at the node NN. Moreover, the inverting buck-boost converter comprises an error amplifier 440 configured to generate a signal indicative of a requested duty-cycle of the signal DRV1 by comparing the feedback signal FBN with a reference signal, such as a reference voltage VREFN, indicative of a requested value for the feedback signal FBN, and thus a requested value for the voltage at the node NP. For example, typically the error amplifier implements a regulator comprising an integral (I) component, and optionally a proportional (P) and/or derivate (D) component. While the error amplifier 440 is shown separately, this error amplifier may also be implemented in the control circuit 444. Accordingly, in this case, the control circuit 444 is configured to generate the PWM drive signal DRV1 having a duty-cycle as indicated by the signal at the output of the error amplifier 440.

Conversely, for low-power applications, the inverting buck-boost converter may be driven with a burst mode. Specifically, in this case, the control circuit 444 may be configured to determine whether the (negative) feedback signal FBN is greater than a (negative) lower threshold. In response to determining that the feedback signal FBP is greater than the lower threshold, the control circuit 444 may generate pulses in the drive signal DRV1 until the control circuit 444 determines that the (negative) feedback signal FBP becomes smaller than an (negative) upper threshold.

As mentioned before, in various embodiments, the control circuit 444 may support a boost converter mode and an inverting buck-boost converter mode. For example, in various embodiments, the control circuit 444 is configured to periodically switch between these modes, i.e., use for a given first time period the boost converter mode and for a given second time period the inverting buck-boost converter mode. For example, in various embodiments, the second time corresponds to the first time, i.e., the control circuit driver uses for 50% the boost converter mode and for 50% the inverting buck-boost converter mode. In various embodiments, the control circuit 444 may also be configured to drive the electronic switches S1 and S2 just during given time periods, i.e., the regulation of the voltages VPP and VNN may be disabled during given time periods. For example, in various embodiments, the control circuit 444 drives the electronic switches S1 and S2 only during the transmission phase when the transmission circuit 100 provides the signal TX and disables the driving of the switches S1 and S2 during the reception phase when the reception circuit 110 analyses the signal RX.

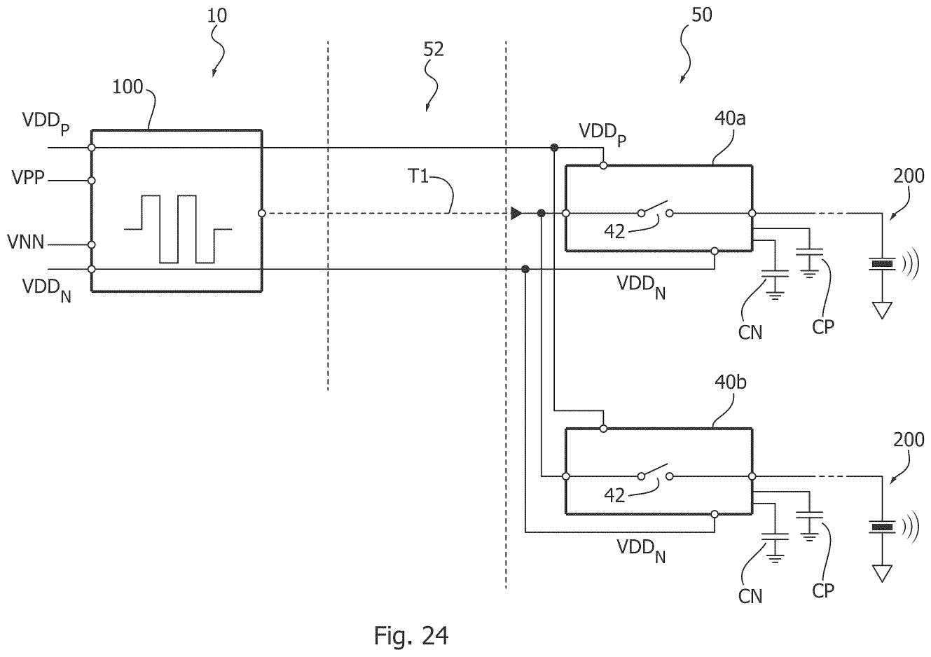

Accordingly, as shown in FIG. 24, various embodiments of the present disclosure relate to an ultrasonic probe 50 adapted to be connected to an ultrasonic system 10. Specifically, the probe 50 comprises a terminal T1, a terminal for receiving the (low positive) supply voltage VDD_{P} and a terminal for receiving the supply voltage VDD_{N}. As mentioned before, in various embodiments, the voltage VDD_{N} may correspond to ground, or preferably corresponds to a (low) negative supply voltage, e.g., VDD_{N}=−VDD_{P}.

In the embodiment considered, the probe 50 comprises at least one switching circuit 40, such as two switching circuits 40a and 40b. Each switching circuit 40 comprises at least one switch 42 configured to selectively connect a respective transducer 200 to the terminal T1. For example, in various embodiments, each switching circuit 40 is implemented with a respective IC, e.g., comprising 8, 16, 32 or 64 switches 42.

Accordingly, in various embodiments, the probe 50 may also comprise one or more terminals for receiving data indicating which switch or switches 42 should be closed. For example, each switching circuit 40 may comprise for this purpose a communication interface, e.g., connected to a shared communication bus. For example, such a bus may be the Serial Peripheral Interface (SPI) or Inter-Integrated Circuit (I²C) protocol, or one of the versions of the Controller Area Network (CAN) bus.

For example, in various embodiments, the terminals T1, VDD_{P}, VDD_{N} and the terminals used for the communication interfaces of the switching circuits 40 are connected via a suitable cable 52, such as a coaxial cable, to the ultrasonic system 10, e.g., comprising the transmission circuit 100 (and possibly the circuits 110, 120 and 130 shown in FIGS. 1 to 3).

Accordingly, in various embodiments, the ultrasonic system 10 may send data to the communication interfaces of the switching circuits 40 in order to close one or more switches 42. In response to receiving these data via the communication interface, each switching circuit 40 may generate the signals SET and RESET for each switch 42 of the switching circuit 40 in order to either close or open the respective switch. Next, the ultrasonic system 10 may apply a pulsed signal to the terminal T1, wherein the signal oscillates between the voltages VPP and VNN.

Alternatively, in various embodiments, each switching circuit 40 comprises terminals for receiving the signals SET and RESET for each electronic switch 42 of the switching circuit 40. For example, in this case, the probe 50 may comprise an additional integrated circuit comprising the communication interface used to exchange data with the ultrasonic system 10, wherein the additional integrated circuit comprises a control circuit configured to generate the signals SET and RESET for the electronic switch 42 as a function of the data received via the communication interface from the ultrasonic system 10.

Accordingly, in the embodiment considered, the cable 52 does not comprise wires for providing the voltages VPP and VNN to the probe 50, but each switching circuit 40 comprises a converter circuit 44 configured to generate internally the voltages having (approximately) the values of the voltages VPP and VNN. For example, the internally generated voltages at the nodes NP and NN may be in a range between 70% and 130%, preferably between 85% and 115%, of the values of the voltages VPP and VNN, respectively. Accordingly, the cable does not need to provide a high voltage supply to the probe 50.

As mentioned before, in various embodiments, the voltages generated by the converter circuit 44 are not used to drive the various switches 42, but are just used to pre-charge one or more internal nodes to the voltages VPP and VNN. In fact, in some technologies, the substrate of the integrated circuit comprising the switching circuit 40 must be placed to the most negative voltage. For example, by connecting the substrate to the node NN, the circuits of FIGS. 21 and 22 may be used to pre-charge the substrate, i.e., the charge is not generated by the negative pulses at the terminal T1, thereby reducing or even avoiding the memory effect.

Accordingly, in various embodiments, the switching circuit 40 comprises a first terminal T1 configured to receive a pulsed signal TX oscillating between a maximum value VPP and a minimum value VNN, and a second terminal T2 configured to be connected to a load 200. Moreover, the switching circuit comprises a first transistor SW₁ and a second SW₂ transistor connected in series between the first terminal T1 and the second terminal T2, wherein the first transistor SW₁ and the second transistor SW₂ comprise a respective control terminal connected to a common control node G, wherein a capacitance C_{GS} is connected between the common control node G and the intermediate point S between the two transistors, wherein the two transistor are rendered conductive or non-conductive as a function of the voltage Fos at the capacitance C_{GS}.

In various embodiments, the switching circuit 40 comprises moreover a positive and a negative power supply terminals for receiving a supply voltage (VDD_{P}, VDD_{N}), wherein the value of the supply voltage is smaller than the amplitude of the pulsed signal. Specifically, in this case, the switching circuit 40 comprises a control circuit (e.g., 310; 410) supplied by the supply voltage (VDD_{P}, VDD_{N}), wherein the control circuit comprises a set circuit (e.g., 312; 412) configured to charge the capacitance C_{GS} as a function of a set signal SET, and a reset circuit (e.g., 314; 414) configured to discharge the capacitance (C_{GS}) as a function of a reset signal (RESET).

Specifically, according to a first aspect of the present disclosure, the switching circuit 40 further comprises a first diode DP1, a second diode DN1 and an electronic converter circuit 44. An anode of the first diode DP1 is connected to the first terminal T1 and a cathode of the first diode DP1 is connected to a first node NP, wherein the first node NP has associated a first capacitance CP. A cathode of the second diode DN1 is connected to the first terminal T1 and an anode of the second diode DN1 is connected to a second node NN, wherein the second node NN has associated a second capacitance CN. The electronic converter circuit 44 is supplied by the supply voltage (VDD_{P}, VDD_{N}) and is configured to (pre) charge the first capacitance CP to a first voltage and the second capacitance CN to a second voltage, thereby reducing or avoiding the previously described memory effect.

According to a second aspect, the control circuit 410b comprises a first diode DA1 having an anode connected to the intermediate point S between the two transistors and a cathode connected to a first supply node FN1, a second diode DA2 having a cathode connected to the intermediate point S and an anode connected to a second supply node FN2, and a plurality of diodes DL1-DLN connected in series between the first supply node FN1 and the second supply node FN2. A logic inverter INVL1 is supplied by the voltage between the first supply node FN1 and the second supply node FN2, wherein an input of the logic inverter INVL1 is connected to the intermediate point S and an output of the logic inverter INVL1 is connected to the common control node G. In this case, the set circuit 412c is configured to connected the first supply node FN1 to the positive power supply terminal (VDD_{P}) as a function of the set signal SET and the reset circuit 414c is configured to connected the second supply node FN2 to the negative power supply terminal (VDD_{N}) as a function of the reset signal RESET.

In general, the first and second aspect may be used independently or in combination.

Of course, without prejudice to the principle of the disclosure, the details of construction and the embodiments may vary widely with respect to what has been described and illustrated herein purely by way of example, without thereby departing from the scope of the present disclosure, as defined by the ensuing claims.

For example, while the solutions in the foregoing have been described with regards to n-channel transistors SW1 and SW2, also p-channel transistors could be used, e.g., by exchanging the signals SET and RESET.

A switching circuit (40) is summarized as including: a first terminal (T1) configured to receive a signal (TX) oscillating between a maximum value (VPP) and a minimum value (VNN); a second terminal (T2) configured to be connected to a load (200); a positive power supply terminal and a negative power supply terminal for receiving a supply voltage (VDD_{P}, VDD_{N}), wherein a value of said supply voltage (VDD_{P}, VDD_{N}) is smaller than an amplitude of said signal (TX); a first (SW₁) transistor and a second (SW₂) transistor connected in series between said first terminal (T1) and said second terminal (T2), wherein each of said first (SW₁) transistor and said second (SW₂) transistor includes a control terminal connected to a common control node (G), wherein a capacitance (C_{GS}) is connected between said common control node (G) and an intermediate point (S) between said first (SW₁) transistor and said second (SW₂) transistor, wherein said first (SW₁) and said second (SW₂) transistor are rendered conductive or non-conductive as a function of the voltage (V_{GS}) at said capacitance (Cas); and a control circuit (310; 410) supplied by said supply voltage (VDD_{P}, VDD_{N}) and including: a set circuit (312; 412) configured to charge said capacitance (C_{GS}) as a function of a set signal (SET), and a reset circuit (314; 414) configured to discharge said capacitance (C_{GS}) as a function of a reset signal (RESET); characterized in that said switching circuit (40) further includes: a first diode (DP1), wherein an anode of said first diode (DP1) is connected to said first terminal (T1) and a cathode of said first diode (DP1) is connected to a first node (NP), wherein said first node (NP) is connected to a first capacitance (C_{P}); a second diode (DN1), wherein a cathode of said second diode (DN1) is connected to said first terminal (T1) and an anode of said second diode (DN1) is connected to a second node (NN), wherein said second node (NN) is connected to a second capacitance (CN); and an electronic converter circuit (44) supplied by said supply voltage (VDD_{P}, VDD_{N}) and configured to charge said first capacitance (C_{P}) to a first voltage and said second capacitance (CN) to a second voltage.

Said first voltage may be in a range between 70% and 130%, preferably between 85% and 115%, of said maximum value (VPP), and/or said second voltage may be in a range between 70% and 130%, preferably between 85% and 115%, of said minimum value (VNN).

Said maximum value (VPP) may be at least 100 V and said supply voltage (VDD_{P}, VDD_{N}) may be smaller than 12 V.

Said minimum value (VNN) may be negative.

Said electronic converter circuit (44) may include a boost converter configured to generate said first voltage at said first node (NP).

Said electronic converter circuit (44) may include an inverting buck-boost converter configured to generate said second voltage at said second node (NN).

Said electronic converter circuit (44) may include: a third terminal (LXN) and a fourth terminal (LXP) configured to be connected to an inductance (L); a first electronic switch (S1) connected between said third terminal (LXN) and said positive supply terminal (VDD_{P}); a second electronic switch (S2) connected between said fourth terminal (LXP) and said negative supply terminal (VDD_{N}); a third electronic switch or a third diode (D1) connected between said third terminal (LXN) and said second node (NN); a fourth electronic switch or a fourth diode (D2) connected between said fourth terminal (LXP) and said first node (NP); a first feedback circuit (R3, R4) configured to provide a first feedback signal (FBP) indicative of the voltage at said first node (NP); a second feedback circuit (R1, R2) configured to provide a second feedback signal (FBN) indicative of the voltage at said second node (NN); a converter control circuit (440, 442, 444) configured to drive said first electronic switch (S1) and said second electronic switch (S2), and optionally said third electronic switch and said fourth electronic switch, in order to regulate said first feedback signal (FBP) to a first reference voltage (VREFP) and said second feedback signal (FBN) to a second reference voltage (VREFN).

Said converter control converter (440, 442, 444) may operate periodically for a first time-period in a boost mode and for a second time-period in an inverting buck-boost mode.

Said control circuit (410) may include a maintenance circuit (416), said maintenance circuit (416) including a plurality of diodes (4162, 4164; 4162₁, 4164₁, 4162₂, 4164₂) and at least one switch (4166; 4168, 4170; 4168, 4170, 4172, 4174) configured such that: a) when the voltage (V_{GS}) at said capacitance (C_{GS}) is greater than a given threshold value (V_{TH}), two diodes (4162, 4164; 4162₁, 4164₁) are connected in cascade between said intermediate point (S) and said common control node (G), thereby enabling current flow from said intermediate point (S) to said common control node (G), and b) when the voltage (V_{GS}) at said capacitance (C_{GS}) is smaller than said given threshold value (V_{TH}), two diodes (4162, 4164; 4162₂, 4164₂) are connected in series between said common control node (G) and said intermediate point (S), thereby enabling current flow from said common control node (G) to said intermediate point (S).

Said control circuit (410b) may include: a fifth diode (DA1) having an anode connected to said intermediate point (S) between said first (SW₁) transistor and said second (SW₂) transistor and a cathode connected to a first supply node (FN1); a sixth diode (DA2) having a cathode connected to said intermediate point (S) between said first (SW₁) transistor and said second (SW₂) transistor and an anode connected to a second supply node (FN2); one or more diodes (DL1-DLN) connected in series between said first supply node (FN1) and said second supply node (FN2); a logic inverter (INVL1) being supplied by the voltage between said first supply node (FN1) and said second supply node (FN2), wherein an input of said logic inverter (INVL1) is connected to said intermediate point (S) and an output of said logic inverter (INVL1) is connected to said common control node (G); wherein said set circuit (412c) is configured to connect said first supply node (FN1) to said positive power supply terminal (VDD_{P}) as a function of said set signal (SET) and said reset circuit (414c) is configured to connected said second supply node (FN2) to said negative power supply terminal (VDD_{N}) as a function of said reset signal (RESET).

The switching circuit (40) may include a clamp circuit (422) configured to connect said intermediate point (S) to ground as a function of said set signal (SET) and said reset signal (RESET).

An integrated circuit is summarized as including a switching circuitry (40) according to any of the previous examples.

An ultrasonic probe (50) configured to be connected via a cable (52) to a pulse generator circuit (10), said ultrasonic probe (50) is summarized as including: a switching circuit (40a, 40b) according to any of the previous examples, wherein an ultrasonic transducer is connected to the second terminal (T2) of said switching circuit (40), and wherein said first terminal (T1), said positive power supply terminal and said negative power supply terminal are configured to be connected via said cable (52) to said pulse generator circuit (10).

An ultrasonic system is summarized as including: a pulse generator circuit (10), and an ultrasonic probe (50) according to the previous example.

A method of operating a switching circuitry (40) according to any of the previous examples, is summarized as including: applying a supply voltage (VDD_{P}, VDD_{N}) to said positive power supply and said negative power supply terminal, whereby said electronic converter circuit (44) charges said first capacitance (CP) to said first voltage and said second capacitance (CN) to said second voltage; generating said set signal (SET) and said second signal (RESET) in order to render said first (SW₁) transistor and said second (SW₂) transistor conductive or non-conductive, and applying an oscillating high-voltage signal to said first terminal (T1).

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A switching circuit comprising:
a first terminal configured to receive a signal oscillating between a maximum value and a minimum value;
a second terminal configured to be connected to a load;
a positive power supply terminal and a negative power supply terminal for receiving a supply voltage, wherein a value of said supply voltage is smaller than an amplitude of said signal;
a first transistor and a second transistor connected in series between said first terminal and said second terminal, wherein each of said first transistor and said second transistor includes a control terminal connected to a common control node, wherein a capacitance is connected between said common control node and an intermediate point between said first transistor and said second transistor, wherein said first transistor and said second transistor are rendered conductive or non-conductive as a function of a voltage at said capacitance; and
a control circuit supplied by said supply voltage and includes:
a set circuit configured to charge said capacitance as a function of a set signal, and
a reset circuit configured to discharge said capacitance as a function of a reset signal;
a first diode, wherein an anode of said first diode is connected to said first terminal and a cathode of said first diode is connected to a first node, wherein said first node is connected to a first capacitance;
a second diode, wherein a cathode of said second diode is connected to said first terminal and an anode of said second diode is connected to a second node, wherein said second node is connected to a second capacitance; and
an electronic converter circuit supplied by said supply voltage and configured to charge said first capacitance to a first voltage and said second capacitance to a second voltage.

2. The switching circuit according to claim 1, wherein said first voltage is in a range between 70% and 130% of said maximum value, and/or said second voltage is in a range between 70% and 130% of said minimum value.

3. The switching circuit according to claim 1, wherein said maximum value is at least 100 V and said supply voltage is smaller than 12 V.

4. The switching circuit according to claim 3, wherein said minimum value is negative.

5. The switching circuit according to claim 1, wherein said electronic converter circuit includes a boost converter configured to generate said first voltage at said first node.

6. The switching circuit according to claim 1, wherein said electronic converter circuit includes an inverting buck-boost converter configured to generate said second voltage at said second node.

7. The switching circuit according to claim 1, wherein said electronic converter circuit includes:
a third terminal and a fourth terminal configured to be connected to an inductance;
a first electronic switch connected between said third terminal and said positive power supply terminal;
a second electronic switch connected between said fourth terminal and said negative power supply terminal;
a third electronic switch or a third diode connected between said third terminal and said second node;
a fourth electronic switch or a fourth diode connected between said fourth terminal and said first node;
a first feedback circuit configured to provide a first feedback signal indicative of the voltage at said first node;
a second feedback circuit configured to provide a second feedback signal indicative of the voltage at said second node;
a converter control circuit configured to drive said first electronic switch and said second electronic switch, in order to regulate said first feedback signal to a first reference voltage and said second feedback signal to a second reference voltage.

8. The switching circuit according to claim 7, wherein said converter control circuit operates periodically for a first time-period in a boost mode and for a second time-period in an inverting buck-boost mode.

9. The switching circuit according to claim 1, wherein said control circuit includes a maintenance circuit, said maintenance circuit includes a plurality of diodes and at least one switch configured such that:
a) when the voltage at said capacitance is greater than a given threshold value, two diodes are connected in series between said intermediate point and said common control node, thereby enabling current flow from said intermediate point to said common control node, and
b) when the voltage at said capacitance is smaller than said given threshold value, the two diodes are connected in series between said common control node and said intermediate point, thereby enabling current flow from said common control node to said intermediate point.

10. The switching circuit according to claim 1, wherein said control circuit includes:
a fifth diode having an anode connected to said intermediate point between said first transistor and said second transistor and a cathode connected to a first supply node;
a sixth diode having a cathode connected to said intermediate point between said first transistor and said second transistor and an anode connected to a second supply node;
one or more diodes connected in series between said first supply node and said second supply node;
a logic inverter supplied by the voltage between said first supply node and said second supply node, wherein an input of said logic inverter is connected to said intermediate point and an output of said logic inverter is connected to said common control node;
wherein said set circuit is configured to connect said first supply node to said positive power supply terminal as a function of said set signal and said reset circuit is configured to connected said second supply node to said negative power supply terminal as a function of said reset signal.

11. The switching circuit according to claim 9, comprising a clamp circuit configured to connect said intermediate point to ground as a function of said set signal and said reset signal.

12. An integrated circuit comprising a switching circuitry according to claim 1.

13. An ultrasonic probe configured to be connected via a cable to a pulse generator circuit, said ultrasonic probe comprising:
a switching circuit according to claim 1, wherein an ultrasonic transducer is connected to the second terminal of said switching circuit, and wherein said first terminal, said positive power supply terminal and said negative power supply terminal are configured to be connected via said cable to said pulse generator circuit.

14. An ultrasonic system comprising:
a pulse generator circuit, and
an ultrasonic probe according to claim 13.

15. A method of operating a switching circuit, the switching circuit including: a first terminal configured to receive a signal oscillating between a maximum value and a minimum value; a second terminal configured to be connected to a load; a positive power supply terminal and a negative power supply terminal for receiving a supply voltage, wherein a value of said supply voltage is smaller than an amplitude of said signal; a first transistor and a second transistor connected in series between said first terminal and said second terminal, wherein each of said first transistor and said second transistor includes a control terminal connected to a common control node, wherein a capacitance is connected between said common control node and an intermediate point between said first transistor and said second transistor, wherein said first transistor and said second transistor are rendered conductive or non-conductive as a function of a voltage at said capacitance; and a control circuit supplied by said supply voltage and including: a set circuit configured to charge said capacitance as a function of a set signal, and a reset circuit configured to discharge said capacitance as a function of a reset signal; a first diode, wherein an anode of said first diode is connected to said first terminal and a cathode of said first diode is connected to a first node, wherein said first node is connected to a first capacitance; a second diode, wherein a cathode of said second diode is connected to said first terminal and an anode of said second diode is connected to a second node, wherein said second node is connected to a second capacitance; and an electronic converter circuit supplied by said supply voltage and configured to charge said first capacitance to a first voltage and said second capacitance to a second voltage, the method comprising:
applying a supply voltage to said positive power supply terminal and said negative power supply terminal, whereby said electronic converter circuit charges said first capacitance to said first voltage and said second capacitance to said second voltage;
generating said set signal and said reset signal in order to render said first transistor and said second transistor conductive or non-conductive, and
applying an oscillating high-voltage signal to said first terminal.
